(19) United States
(12) Patent Application Publication
(10) Pub. No.: US 2025/0315578 A1
(43) Pub. Date: Oct. 9, 2025

(54) MULTI-POROSITY MULTI-PERMEABILITY EMBEDDED DISCRETE FRACTURE METHOD FOR EFFICIENT SIMULATION OF FRACTURED RESERVOIRS IN A PARALLEL RESERVOIR SIMULATOR

(71) Applicant: ARAMCO SERVICES COMPANY, Houston, TX (US)

(72) Inventors: Shuang Zheng, Houston, TX (US); Yashod Savithru Jayasinghe, Framingham, MA (US); Todd Ferguson, Houston, TX (US)

(73) Assignee: ARAMCO SERVICES COMPANY, Houston, TX (US)

(21) Appl. No.: 18/630,508

(22) Filed: Apr. 9, 2024

(51) Int. Cl. G06F 30/28

(52) U.S. Cl. CPC G06F 30/28

(57) ABSTRACT

Reservoir simulation is performed by constructing an embedded discrete fracture model (EDFM) having matrix grid cells and extra continuum grid cells in the simulation grid. The EDFM is integrated into a multi-porosity-multi-permeability (MPMP) framework of a parallel reservoir simulator. Each fracture polygon of the fractures in the reservoir is divided into a set of fracture cells for calculating matrix-fracture connections and fracture-fracture connections, which are all neighbor connections between grid cells that are face or edge neighbors. These neighbor connections may be intra-continuum connections or inter-continua connections that are stored in the matrix grid cells and/or fracture grid cells in the integrated EDFM/MPMP framework. The reservoir simulation is performed by the parallel reservoir simulator based on the cell connectivity data in the integrated EDFM/MPMP framework to facilitate well production of the reservoir.

### BACKGROUND

Mine-back experiments, lab experiments, and core analysis of fractured rocks show that hydraulic-natural fractures are quite complex after stimulation. In tight or shale oil or gas reservoirs, the permeability of the matrix remains at an extremely low value (e.g., 1 micro-Darcy to 1 nano-Darcy), which makes it infeasible to commercially extract oil and gas from these kinds of reservoirs. Therefore, hydraulic fracturing is an essential process in the development of tight shale reservoirs. During hydraulic fracturing, a mixture of fracturing fluids and proppants are pumped underground to create a high conductivity fracture network which is supported by the proppant and remains conductive during well production. Existing natural fractures may also be activated by the hydraulic fractures and form a complex, interconnected fracture network. These highly conductive fractures play an important role and control the production performance of tight/shale reservoirs. Hence, the ability to model the flow accurately and efficiently within the coupled fracture-matrix system becomes an important task in unconventional reservoir simulation.

### SUMMARY

In general, in one aspect, the invention relates to a method to perform reservoir simulation of a reservoir. The method includes generating a simulation grid to represent the reservoir for the reservoir simulation, the simulation grid comprising a matrix grid and a continuum grid that superimpose each other, wherein each of a plurality of matrix cells of the matrix grid corresponds to one of a plurality of continuum cells of the continuum grid, wherein said each of the plurality of matrix cells stores corresponding rock properties of the reservoir, obtaining fracture geometry data that represents a fracture polygon of each of a plurality of fractures in the reservoir, obtaining well trajectory data that represents well segments of each of a plurality of wellbores in the reservoir, dividing, based on the matrix grid, each fracture polygon into a set of fracture cells, calculating fracture cell geometry data that represents each fracture cell of the plurality of fractures, storing, for said each fracture cell, the fracture cell geometry data in a continuum cell of the plurality of continuum cells, wherein the continuum cell corresponds to a matrix cell of the plurality of matrix cells that contains said each fracture cell, calculating matrix-fracture connections and fracture-fracture connections, wherein the matrix-fracture connections represent connectivity between the plurality of matrix cells and each fracture cell of the plurality of fractures, wherein the fracture-fracture connections represent connectivity among all fracture cells of the plurality of fractures, calculating wellbore-fracture connections, wherein the wellbore-fracture connections (perforation locations and productivity indices) represents the connectivity between plurality of fracture cells and the intersecting well segments, generating a reservoir simulation result by performing the reservoir simulation based on the matrix grid with stored rock properties, the continuum grid with stored fracture cell geometry data, the matrix-fracture connections, the fracture-fracture connections, and the wellbore-fracture connections, and performing, based on the reservoir simulation result, well production of the reservoir.

In general, in one aspect, the invention relates to a modeling engine to facilitate reservoir simulation of a reservoir. The modeling engine includes a computer processor, and memory storing instructions, when executed by the computer processor comprising functionality for generating a simulation grid to represent the reservoir for the reservoir simulation, the simulation grid comprising a matrix grid and one or more continuum grids that superimpose each other, wherein each of a plurality of matrix cells of the matrix grid corresponds to one of a plurality of continuum cells of the continuum grids, wherein said each of the plurality of matrix cells stores corresponding rock properties of the reservoir, obtaining fracture geometry data that represents a fracture polygon of each of a plurality of fractures in the reservoir, dividing, based on the matrix grid, each fracture polygon into a set of fracture cells, calculating fracture cell geometry data that represents each fracture cell of the plurality of fractures, storing, for said each fracture cell, the fracture cell geometry data in a continuum cell of the plurality of continuum cells, wherein the continuum cell corresponds to a matrix cell of the plurality of matrix cells that contains said each fracture cell, and calculating matrix-fracture connections, fracture-fracture connections, fracture-wellbore connections, wherein the matrix-fracture connections represent connectivity between the plurality of matrix cells and each fracture cell of the plurality of fractures, wherein the fracture-fracture connections represent connectivity among all fracture cells of the plurality of fractures, wherein the fracture-wellbore connections (perforation locations and productivity indices) represent connectivity between fracture cells of the plurality of fractures and well segments of the plurality of well trajectories, wherein a reservoir simulation result is generated by performing the reservoir simulation based on the matrix grid with stored rock properties, the continuum grid with stored fracture cell geometry data, the matrix-fracture connections, and the fracture-fracture connections, and fracture-wellbore connections (perforation locations and productivity indices), and wherein well production of the reservoir is performed based on the reservoir simulation result.

In general, in one aspect, the invention relates to a system that includes a wellsite for performing well production of a reservoir and a modeling engine to facilitate reservoir simulation of the reservoir. The modeling engine includes a computer processor, and memory storing instructions, when executed by the computer processor comprising functionality for generating a simulation grid to represent the reservoir for the reservoir simulation, the simulation grid comprising a matrix grid and a continuum grid that superimpose each other, wherein each of a plurality of matrix cells of the matrix grid corresponds to one of a plurality of continuum cells of the continuum grid, wherein said each of the plurality of matrix cells stores corresponding rock properties of the reservoir, obtaining fracture geometry data that represents a fracture polygon of each of a plurality of fractures in the reservoir, obtaining well trajectory data that represents well segments of each of a plurality of wellbores in the reservoir, dividing, based on the matrix grid, each fracture polygon into a set of fracture cells, calculating fracture cell geometry data that represents each fracture cell of the plurality of fractures, storing, for said each fracture cell, the fracture cell geometry data in a continuum cell of the plurality of continuum cells, wherein the continuum cell corresponds to a matrix cell of the plurality of matrix cells that contains said each fracture cell, calculating matrix-fracture connections and fracture-fracture connections, wherein the matrix-fracture connections represent connectivity between the plurality of matrix cells and each fracture cell of the plurality of fractures, wherein the fracture-fracture connections represent connectivity among all fracture cells of the plurality of fractures, and calculating wellbore-fracture connections, wherein the wellbore-fracture connections (perforation locations and productivity indices) represents the connectivity between plurality of fracture cells and the intersecting well segments, and a reservoir simulator that generates a reservoir simulation result by performing the reservoir simulation based on the matrix grid with stored rock properties, the continuum grid with stored fracture cell geometry data, the matrix-fracture connections, the fracture-fracture connections, and the wellbore-fracture connections, wherein the well production of the reservoir is performed based on the reservoir simulation result.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIGS. 1A-1B show a system in accordance with one or more embodiments.

FIG. 2 shows a method flowchart in accordance with one or more embodiments.

FIGS. 3-31 show examples in accordance with one or more embodiments.

FIG. 32 shows a computing system in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (for example, first, second, third) may be used as an adjective for an element (that is, any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

In general, embodiments of the disclosure include a method and system for performing reservoir simulation in a reservoir. The reservoir simulation is based on a simulation grid of the reservoir that includes simulation grid that partitions the reservoir into a set of grid blocks, referred to as a continuum grid where each grid block may contain a matrix grid cell and one or more extra continuum grid cells. In particular, the matrix grid cells store rock properties of the reservoir and the extra continuum grid cells store information regarding fractures in the reservoir. An embedded discrete fracture model (EDFM) is constructed based on combining the matrix grid cells and extra continuum grid cells in the simulation grid. In one or more embodiments, the EDFM is integrated into a multi-porosity-multi-permeability (MPMP) framework of a parallel reservoir simulator. To form the data structures associated with the integrated EDFM/MPMP framework, each fracture polygon of the fractures in the reservoir is divided into a set of fracture cells that are used as the basis for calculating matrix-fracture connections and fracture-fracture connections. As the matrix grid cells and the extra continuum grid cells are superimposed in physical space, the matrix-fracture connections and fracture-fracture connections are all neighbor connections between grid cells that are face or edge neighbors. These neighbor connections may be intra-continuum connections or inter-continua connections that are stored in the matrix grid cells and/or fracture grid cells in the integrated EDFM/MPMP framework. In one or more embodiments, the reservoir simulation is performed by the parallel reservoir simulator based on the cell connectivity data in the integrated EDFM/MPMP framework to facilitate well production of the reservoir.

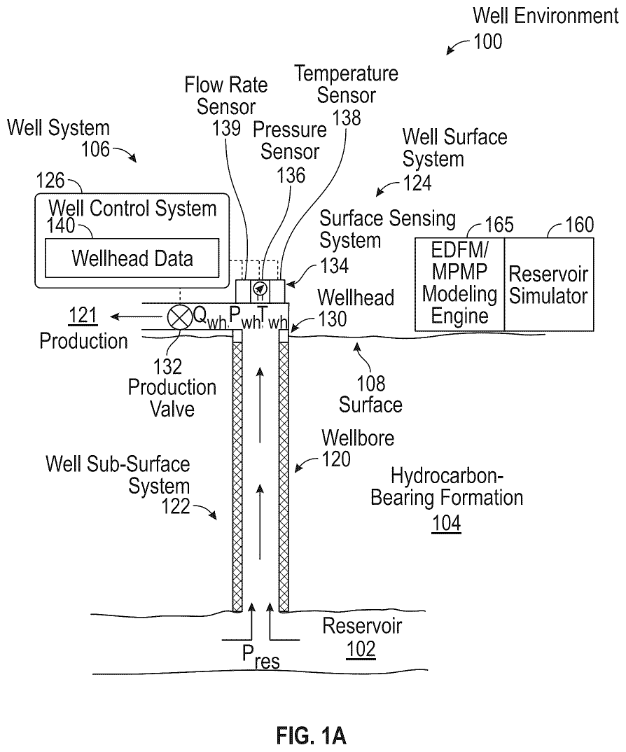

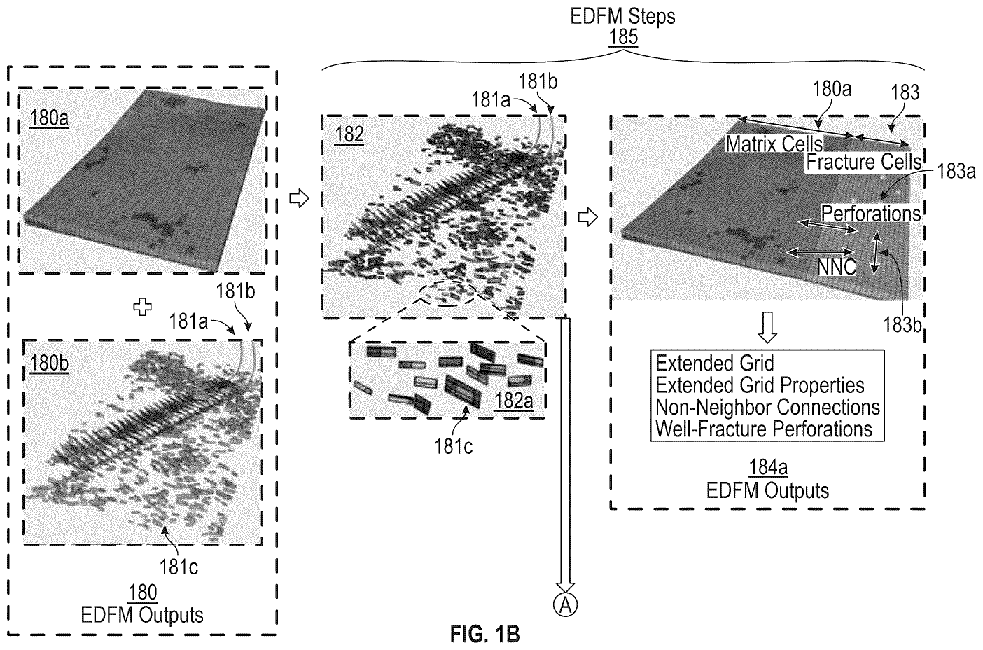

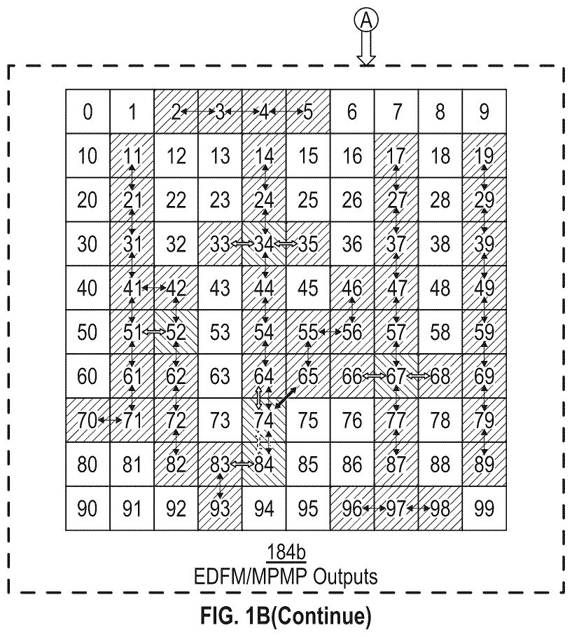

FIG. 1A shows a schematic diagram in accordance with one or more embodiments. More specifically, FIG. 1A illustrates a well environment (100) that includes a hydrocarbon reservoir (“reservoir”) (102) located in a subsurface hydrocarbon-bearing formation (“formation”) (104) and a well system (106). For example, the reservoir (102) may be an oil reservoir or a gas reservoir. The hydrocarbon-bearing formation (104) may include a porous or fractured rock formation that resides underground, beneath the Earth's surface (“surface”) (108). In the case of the well system (106) being a hydrocarbon well, the reservoir (102) may include a portion of the hydrocarbon-bearing formation (104). The hydrocarbon-bearing formation (104) and the reservoir (102) may include different layers of rock (referred to as formation layers) having varying characteristics, such as varying degrees of permeability, porosity, capillary pressure, and resistivity. In the case of the well system (106) being operated as a production well, the well system (106) may facilitate the extraction of hydrocarbons (or “production”) from the reservoir (102).

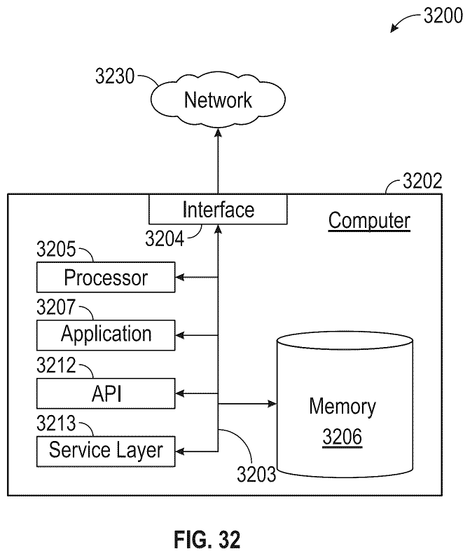

In some embodiments, the well system (106) includes a wellbore (120), a well sub-surface system (122), a well surface system (124), and a well control system (“control system”) (126). The control system (126) may control various operations of the well system (106), such as well production operations, well completion operations, well maintenance operations, and reservoir monitoring, assessment and development operations. In some embodiments, the control system (126) includes a computer system that is the same as or similar to that of the computer system (3200) described below in FIG. 32 and the accompanying description.

The wellbore (120) may include a bored hole that extends from the surface (108) into a target zone of the hydrocarbon-bearing formation (104), such as the reservoir (102). An upper end of the wellbore (120), terminating at or near the surface (108), may be referred to as the “up-hole” end of the wellbore (120), and a lower end of the wellbore, terminating in the hydrocarbon-bearing formation (104), may be referred to as the “down-hole” end of the wellbore (120). The wellbore (120) may facilitate the circulation of drilling fluids during drilling operations, the flow of hydrocarbon production (“production”) (121) (e.g., oil and gas) from the reservoir (102) to the surface (108) during production operations, the injection of substances (e.g., water) into the hydrocarbon-bearing formation (104) or the reservoir (102) during injection operations, or the communication of monitoring devices (e.g., logging tools) into the hydrocarbon-bearing formation (104) or the reservoir (102) during monitoring operations (e.g., during in situ logging operations).

In some embodiments, during operation of the well system (106), the control system (126) collects and records wellhead data (140) for the well system (106). The wellhead data (140) may include, for example, a record of measurements of wellhead pressure (P_{wh}) (e.g., including flowing wellhead pressure), wellhead temperature (T_{wh}) (e.g., including flowing wellhead temperature), wellhead production rate (Q_{wh}) over some or all of the life of the well system (106), and water cut data. In some embodiments, the measurements are recorded in real-time, and are available for review or use within seconds, minutes or hours of the condition being sensed (e.g., the measurements are available within 1 hour of the condition being sensed). In such an embodiment, the wellhead data (140) may be referred to as “real-time” wellhead data (140). Real-time wellhead data (140) may enable an operator of the well system (106) to assess a relatively current state of the well system (106), and make real-time decisions regarding development of the well system (106) and the reservoir (102), such as on-demand adjustments in regulation of production flow from the well.

In some embodiments, the well sub-surface system (122) includes casing installed in the wellbore (120). For example, the wellbore (120) may have a cased portion and an uncased (or “open-hole”) portion. The cased portion may include a portion of the wellbore having casing (e.g., casing pipe and casing cement) disposed therein. The uncased portion may include a portion of the wellbore not having casing disposed therein. In some embodiments, the casing includes an annular casing that lines the wall of the wellbore (120) to define a central passage that provides a conduit for the transport of tools and substances through the wellbore (120). For example, the central passage may provide a conduit for lowering logging tools into the wellbore (120), a conduit for the flow of production (121) (e.g., oil and gas) from the reservoir (102) to the surface (108), or a conduit for the flow of injection substances (e.g., water) from the surface (108) into the hydrocarbon-bearing formation (104). In some embodiments, the well sub-surface system (122) includes production tubing installed in the wellbore (120). The production tubing may provide a conduit for the transport of tools and substances through the wellbore (120). The production tubing may, for example, be disposed inside casing. In such an embodiment, the production tubing may provide a conduit for some or all of the production (121) (e.g., oil and gas) passing through the wellbore (120) and the casing.

In some embodiments, the well surface system (124) includes a wellhead (130). The wellhead (130) may include a rigid structure installed at the “up-hole” end of the wellbore (120), at or near where the wellbore (120) terminates at the Earth's surface (108). The wellhead (130) may include structures for supporting (or “hanging”) casing and production tubing extending into the wellbore (120). Production (121) may flow through the wellhead (130), after exiting the wellbore (120) and the well sub-surface system (122), including, for example, the casing and the production tubing. In some embodiments, the well surface system (124) includes flow regulating devices that are operable to control the flow of substances into and out of the wellbore (120). For example, the well surface system (124) may include one or more production valves (132) that are operable to control the flow of production (121). For example, a production valve (132) may be fully opened to enable unrestricted flow of production (121) from the wellbore (120), the production valve (132) may be partially opened to partially restrict (or “throttle”) the flow of production (121) from the wellbore (120), and production valve (132) may be fully closed to fully restrict (or “block”) the flow of production (121) from the wellbore (120), and through the well surface system (124).

Continuing with FIG. 1A, in some embodiments, the well surface system (124) includes a surface sensing system (134). The surface sensing system (134) may include sensors for sensing characteristics of substances, including production (121), passing through or otherwise located in the well surface system (124). The characteristics may include, for example, pressure, temperature and flow rate of production (121) flowing through the wellhead (130), or other conduits of the well surface system (124), after exiting the wellbore (120).

In some embodiments, the surface sensing system (134) includes a surface pressure sensor (136) operable to sense the pressure of production (121) flowing through the well surface system (124), after it exits the wellbore (120). The surface pressure sensor (136) may include, for example, a wellhead pressure sensor that senses a pressure of production (121) flowing through or otherwise located in the wellhead (130). In some embodiments, the surface sensing system (134) includes a surface temperature sensor (138) operable to sense the temperature of production (121) flowing through the well surface system (124), after it exits the wellbore (120). The surface temperature sensor (138) may include, for example, a wellhead temperature sensor that senses a temperature of production (121) flowing through or otherwise located in the wellhead (130), referred to as “wellhead temperature” (T_{wh}). In some embodiments, the surface sensing system (134) includes a flow rate sensor (139) operable to sense the flow rate of production (121) flowing through the well surface system (124), after it exits the wellbore (120). The flow rate sensor (139) may include hardware that senses a flow rate of production (121) (Q_{wh}) passing through the wellhead (130).

In some embodiments, the well system (106) includes a reservoir simulator (160). For example, the reservoir simulator (160) may include hardware and/or software with functionality for generating one or more reservoir models regarding the hydrocarbon-bearing formation (104) and/or performing one or more reservoir simulations based on the one or more reservoir models. For example, the reservoir simulator (160) may store well logs and data regarding reservoir samples for performing simulations. For example, the reservoir samples may include core samples and/or oil/gas/water sample obtained from the reservoir. A reservoir simulator may further analyze the well log data, the reservoir sample data, seismic data, and/or other types of data to generate and/or update the one or more reservoir models. While the reservoir simulator (160) is shown at a well site, embodiments are contemplated where reservoir simulators are located away from well sites. In some embodiments, the reservoir simulator (160) may include a computer system that is similar to the computer system (3200) described below with regard to FIG. 32 and the accompanying description.

In a typical reservoir simulation, a mathematical model of the reservoir (e.g., reservoir (102)) includes a set of partial differential equations representing the reservoir and well flows that are solved numerically. Numerical solution involves time and space/domain discretization replacing differential equations with difference equations. Time discretization refers to the division of time into a sequence of time steps. In each time step, the nonlinear system of equations produced by the space-time discretization is solved using Newton's method, which may take several Newton iterations to converge. Space/domain discretization, also called grid generation, refers to the division of the reservoir/formation domain into a grid of small grid blocks. A grid is a tessellation of a set of contiguous polygonal (2D) or polyhedral (3D) objects referred to as grid blocks/cells/elements/control volumes. The grid is also referred to as reservoir grid, formation grid, or matrix grid according to the context. The grid generation is a process of discretizing the reservoir/formation using both structured and more complex unstructured grid blocks to accurately represent the geometry of the reservoir/formation. Throughout this disclosure, the term “grid cell” or simply “cell” refers to a geometric volume as well as an associated data storage location (e.g., memory location) that stores information related to the geometric volume and any geometric or physical objects contained therein. The collection of data storage locations throughout a formation grid collectively store information (e.g., rock properties, fracture data, etc.) related to the corresponding formation domain (e.g., a reservoir or a portion thereof) and is referred to as a continuum or a continuum grid. In this context, each data storage location associated with a grid cell is referred to as a continuum cell of the continuum grid that corresponds to the grid cell of the formation grid. A grid may be extended to include extra or additional continua described in detail below. Local grid refinement (i.e., a finer grid is selectively embedded inside a coarse grid) is also a feature provided by many simulators to represent the near wellbore multi-phase flow effects more accurately.

Numerical schemes used in reservoir simulation are control volume distributed (CVD). Rock properties such as permeability and porosity, and flow properties such as pressure, temperature, and composition (saturation) are assumed piecewise constant within a control volume (i.e., grid block). However, reservoir and flow properties may jump by order of magnitude across the faces of the control volumes (i.e., grid blocks). Consequently, property distribution in reservoir simulation is stair step, and rate of change of a property across grid blocks depends on grid resolution. Lack of definition within a single grid block and sharp changes in pressure and saturation across the grid blocks create several physical, numerical, and convergence problems during the reservoir simulation.

In numerical simulation, dynamic interaction between hydrocarbon reservoirs and wells may be modeled using reservoir boundary conditions in the form of well controls to match historical data and/or define operational limits for reservoir forecasting. For example, the reservoir simulation may be used to predict or forecast field performance and ultimate recovery for various field development scenarios to evaluate the effects on recovery of different operational conditions and compare economics of different recovery methods.

To predict or forecast field performance and ultimate recovery of tight reservoirs, different models have been developed to model fracture systems (e.g., in the formation (104) and/or reservoir (102)), such as the multi-porosity-multi-permeability (MPMP) model, local grid refinement, unstructured grids, and embedded discrete fracture model (EDFM).

Generally, the local grid refinement (LGR) approach has been widely used to model hydraulic fractures in horizontal wells. However, the low computational efficiency of traditional LGR solutions limits the number of wells that can be simulated, as most of these studies only consider one or a few wells in their models. In addition, LGR methods on structured grids can be greatly inefficient and inaccurate in capturing the complex, non-axis aligned geometries of hydraulic and natural fracture networks. Although unstructured grids (i.e., grids with non-axis aligned cells) can be used to model complex fracture networks, their usage in multi-well simulations is still limited due to the complexity of grid generation, especially as more wells and fractures are considered.

Using the MPMP model, it may be difficult to estimate the transfer coefficient between the matrix (i.e., the underlying reservoir/formation material where fractures exist) and fractures. It may also be difficult to model complex fracture geometry, especially when the fractures are not aligned with the grid in the matrix. The transmissibility between the fracture cells (i.e., cells where fractures exist) is also a grid dependent function of the cell volume and face area.

Embedded discrete fracture models (EDFM) are a class of models where fracture and matrix grids are constructed independently, and then coupled to each other via source/sink relations. EDFM calculations are typically performed as a preprocessing step for a reservoir simulator. EDFM enables complex fracture geometry to be discretized and embedded in the structured matrix cells via non-neighbor connections (NNC), which avoids gridding complexities caused by local grid refinement or unstructured gridding techniques. FIG. 1B illustrates example EDFM calculations that are typically performed as a preprocessing step for a reservoir simulator, such as the reservoir simulator (160). EDFM calculations consist of four key steps (185) using the matrix grid (180a) and the fracture geometry (180b) as the EDFM inputs (180). For example, matrix properties are represented as greyish shades throughout the matrix grid (180a). The fracture geometry (180b) describes geometric shapes of individual fractures (e.g., fracture (181c)) and well trajectories (e.g., trajectories (181a, 181b)). In the first step, each fracture in the fracture geometry (180b) is discretized by the matrix grid (180a) into several fracture cells to generate the discretized fracture geometry (182) where the cross-sectional areas and distances of individual fracture cells to the matrix cells are calculated. A fracture cell is a portion of a fracture within each of the cells where the fracture exists. For example, as shown within the expanded view (182a) of a portion of the discretized fracture geometry (182), the fracture (181c) is divided by grid lines of the matrix grid (180a) into several fracture cells.

In the second step, the connections between fracture cells within the same fracture are checked. The fracture cell to fracture cell intersection area and distance are calculated. In the third step, the connections (intersection) between fracture planes are checked. The cross-sectional areas and distances of fracture cells in different fracture planes are calculated.

In the fourth step, the fracture plane to well trajectory intersections (referred to as perforations, such as the perforation (183a)) are calculated. Upon completion of these four steps, the original matrix grid (180a) is extended by appending the additional fracture cells (183) to the side of the matrix grid (180a) as an extended grid. Non-neighbor connections (referred to as NNCs, such as the NNC (183b)) are defined to represent matrix-to-fracture and fracture-to-fracture communication between physically connected cells that are not adjacent in the computational grid. The well productivity index at the well-to-fracture intersection is also calculated. Finally, the extended grid, extended grid properties, non-neighbor connections, and well-fracture perforation and productivity indices are output as EDFM outputs (184a) and stored in memory (e.g., computer memory or disk storage device) for a reservoir simulator to access and use as the grid for the reservoir/formation model. In the conventional embedded discrete fracture model (EDFM), the extended grid and other components of the EDFM outputs (184a) are used within a single porosity-single permeability (SPSP) reservoir simulation, with non-neighbor connections (NNC) representing the matrix-fracture and fracture-fracture connections.

In some embodiments, the well system (106) includes an EDFM/MPMP modeling engine (165). For example, the EDFM/MPMP modeling engine (165) may include hardware and/or software with functionality that generates extra continua on the original reservoir grid for modeling fracture flow in a parallel reservoir simulator. Fracture geometry data representing the shape, width, and permeability of each fracture is first read in by a parallel reservoir simulator. These fractures are then intersected with the matrix grid and the resulting discrete fracture cells are inserted into the multiple porosity, multiple permeability (MPMP) framework of a parallel reservoir simulator with the calculated transmissibility for matrix-fracture, and fracture-fracture connections. This workflow performed by the EDFM/MPMP modeling engine (165) supports nested local grid refinements around the hydraulic fractures in a level-set pattern, as specified by the user.

In one or more embodiments, the EDFM/MPMP modeling engine (165) integrates the embedded discrete fracture model (EDFM) into the MPMP framework of a parallel reservoir simulator. Fracture-fracture (F-F), fracture-matrix (F-M) connections, transmissibility, and fracture cell porosities are calculated using EDFM based on the input fracture width, permeability, and geometry data. Unlike traditional EDFM outputs (184a) which extends the original grid by appending fracture cells on the side and uses special non-neighbor connection functionalities provided by the reservoir simulator to represent the F-F and F-M connections, in the workflow performed by the EDFM/MPMP modeling engine (165), the fracture cells are assigned to different continua in the MPMP framework and the non-neighbor connections in EDFM are converted to inter-continua and intra-continuum neighbor connections in MPMP. In this context, a continuum or continuum grid refers to the set of grid cells belonging to a particular continuum, such as matrix or fracture. The continuum grids superimpose each other and occupy the same physical space in the reservoir grid, such that a single reservoir grid block may contain a matrix continuum cell and/or multiple fracture continuum cells. The F-F and F-M transmissibilities and fracture porosities are stored in the extra continua and combined with the matrix grid to form the EDFM/MPMP outputs (184b), which are fed into the MPMP framework to perform the reservoir simulation. Details of the EDFM/MPMP outputs (184b) are described in reference to FIG. 16 below.

The EDFM/MPMP modeling workflow preserves the efficiency of grid generation and computational efficiency of MPMP while maintaining the accuracy and flexibility of EDFM in modeling 3D hydraulic and natural fracture geometry. The workflow uses fracture permeability and width as inputs rather than the exchange coefficients used in conventional MPMP models. It also avoids appending additional cells to the original grid, which is a time-consuming process for large models and makes model visualization and analysis more cumbersome. In one or more embodiments, the EDFM/MPMP modeling engine (165) executes the workflow using parallel computing, which significantly speeds up simulation setup time by leveraging the power of parallel computers.

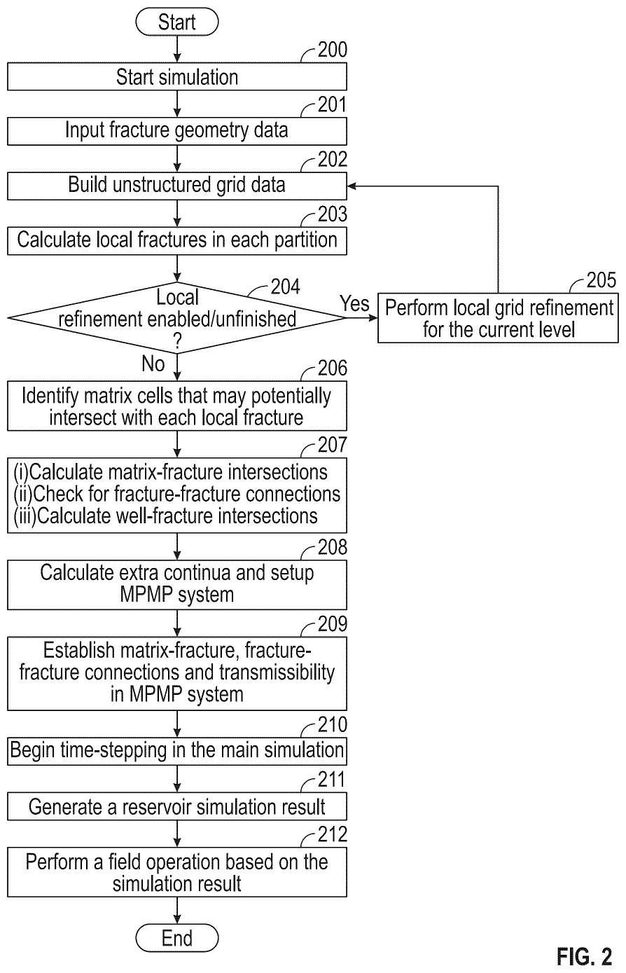

FIG. 2 shows a flowchart in accordance with one or more embodiments disclosed herein. One or more of the steps in FIG. 2 may be performed by components of the well environment (100), the reservoir simulator (160), and the EDFM/MPMP modeling engine (165) discussed above in reference to FIGS. 1A-1B. In one or more embodiments, one or more of the steps shown in FIG. 2 may be omitted, repeated, and/or performed in a different order than the order shown in FIG. 2. Accordingly, the scope of the disclosure should not be considered limited to the specific arrangement of steps shown in FIG. 2.

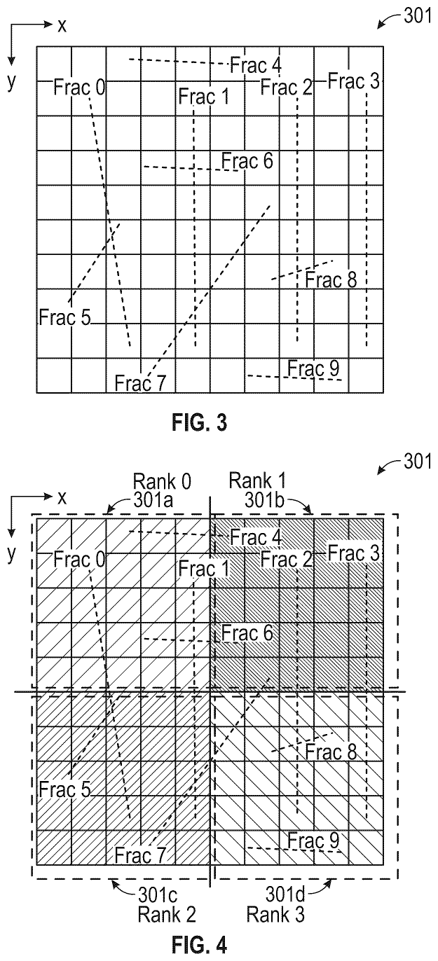

FIGS. 3-17 illustrate the steps shown in FIG. 2 for a simplified two-dimensional (2D) example with 10 fractures on a 10×10 grid. The 2D example is chosen for illustration purposes and easily extended to a three-dimensional (3D) example as well.

Initially in Step 200, the simulation is started. In one or more embodiments, the reservoir simulator starts a simulation session and requests the EDFM/MPMP modeling engine to generate an EDFM grid for the area of interest, such as a portion of the reservoir.

In Step 201, the fracture geometry data is obtained as input to the EDFM/MPMP modeling engine. The fracture geometry data, such as the polygon vertices, width, permeability etc., of the 10 fractures denoted as Frac 1 through Frac 10 in the example 10×10 grid (301) shown in FIG. 3, is either input by the user or imported from a hydraulic fracturing simulator. Each inputted or imported fracture is assigned a global index, such as indices 1 through 10 for the 10 example fractures shown in FIG. 3. Additional examples shown in FIGS. 4-17 below are based on the grid (301) and 10 example fractures, or a portion thereof. Throughout this disclosure, the shape and area of the fracture may be referred to as the fracture polygon. The terms “fracture” and “fracture polygon” may be used interchangeably depending on the context. Although the 10×10 grid (301) depicts cells having the same shape and size, variations of the grid (301) may be based on its type, such as block-centered grid (BCG), corner-point grid (CPG), or perpendicular bisector (PEBI) grid. The geometry data can be stored in binary or ASCII file formats. The fracture geometry data is read in and stored in distributed memory accessible by multiple computer processors (i.e., CPUs) of the EDFM/MPMP modeling engine. FIG. 4 shows an example scenario where the 10×10 grid (301) is decomposed or otherwise divided into 4 partitions denoted as Rank 0 through Rank 3 and distributed to 4 CPUs for processing. In the description below, each CPU is referred to as one of Ranks 0 through 3 corresponding to the partition processed by the CPU. For example, the CPU processing the Rank 0 partition is also referred to as Rank 0. The fractures are distributed into each rank uniformly. In the first round of distribution, each rank receives 10/4=2 fractures. Then the 10 fractures read in are distributed in the following ways: Rank 0 (301a) stores Frac 0, 1. Rank 1 (301b) stores Frac 2, 3. Rank 2 (301c) stores Frac 4, 5. Rank 3 (301d) stores Frac 6, 7. There are two more fractures left (frac 8, 9). Then another round of distribution across all ranks is performed based on the rank number: Frac 8 is distributed to rank 0 and Frac 9 is distributed to rank 1. TABLE 1 lists the final distribution of the 10 fractures. However, the way how the fractures are distributed into different ranks does not affect the EDFM/MPMP computing.

TABLE 1

| Rank number | Fractures stored |
|---|---|
| 0 | Fracs 0, 1, 8 |
| 1 | Fracs 2, 3, 9 |
| 2 | Fracs 4, 5 |
| 3 | Fracs 6, 7 |

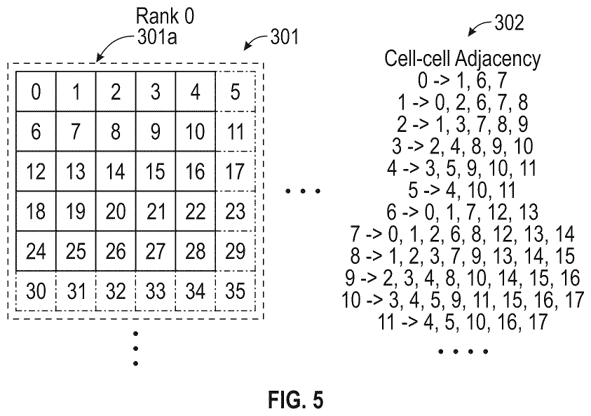

In Step 202, unstructured grid data is constructed by the EDFM/MPMP modeling engine from the block-center grid (BCG), corner-point grid (CPG), or perpendicular bisector (PEBI) grid of the initial matrix grid (301). The unstructured grid data include cell geometry (e.g., points, faces, edges), cell-to-cell connectivity, and a flag to identify if the cell is owned by (i.e., belongs to) the current grid partition. FIG. 5 shows a portion of the grid (301) where each grid cell is given a continuous local cell index from 0 to 35. In contrast to the cells represented by black boxes in FIG. 5, which are owned by Rank 0, the other cells represented by green boxes are referred to as “outer halo” cells, which means that these cells are owned by other ranks, but their information is also duplicated on Rank 0 and utilized by Rank 0. The cell-to-cell adjacency is constructed by geometric calculations involving both face-to-face neighbors (or face neighbors) and edge-to-edge neighbors (or edge neighbors). For example, cell 0 has the cell-to-cell adjacency of face neighbor cells 1 and 6 as well as edge neighbor cell 7. List (302) shows a portion of cell-to-cell adjacency of the grid (301). In particular, the list (302) shows the cell-to-cell adjacency of cells 0 through 11.

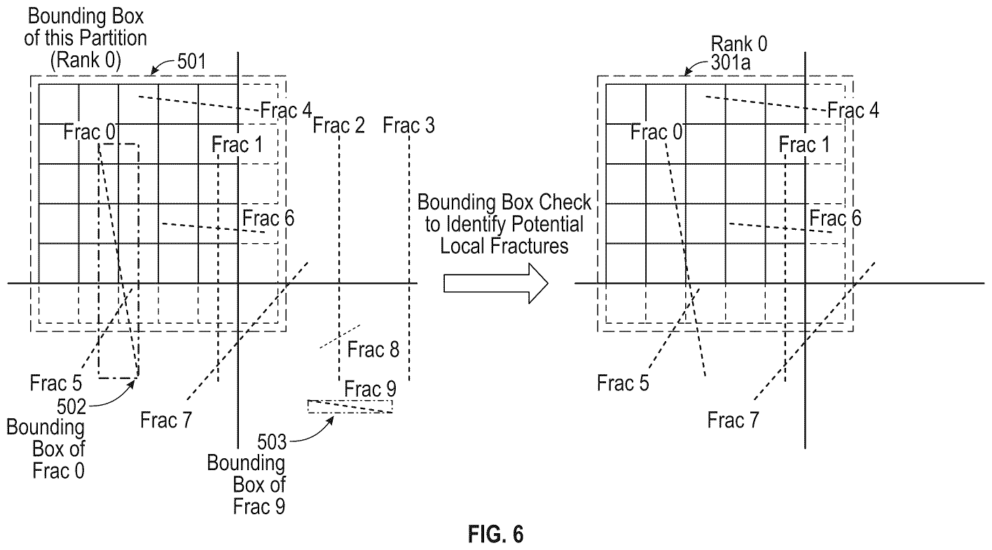

In Step 203, local fractures in each partition of the unstructured grid (301) are calculated by comparing the bounding box of one fracture with respect to the bounding boxes of all cells within a partition or more specifically within the partition bounding box. For example, the black dash-line box depicted in FIG. 6 is the partition bounding box of the partition Rank 0 (501). Firstly, in the rank sequence Rank 0 through Rank 3, the locally stored fracture data is broadcasted to all other ranks (i.e., CPUs). Within each rank, for each fracture, a bounding box check is performed as follows: if the bounding box of one fracture intersects or overlaps the partition bounding box, then this fracture is marked as local to this partition and stored in this partition to be used for further processing. In the example shown in FIG. 6, Rank 0 determines that Frac 0 is local because Frac 0's bounding box (502) intersects Rank 0's partition bounding box (501). Another example is that Frac 9 is not local to Rank 0 because Rank 0's partition bounding box (501) does not intersect with the bounding box (503) of Frac 9. After all the checks, each rank stores its locally owned fractures. For example, Rank 0 stores its local fracs 0, 1, 4, 5, 6, 7. Rank 1 stores its local fracs 1, 2, 3, 4, 6, 7. Rank 2 stores its local fracs 0, 1, 5, 7. Rank 3 its local stores fracs 1, 2, 3, 7, 8, 9.

In Step 204, a determination is made as to whether local grid refinement (LGR) is enabled and unfinished. If the determination is positive, the method proceeds to Step 205 to perform LGR for the current level before returning to Step 202. If the determination is negative, the method proceeds to Step 206.

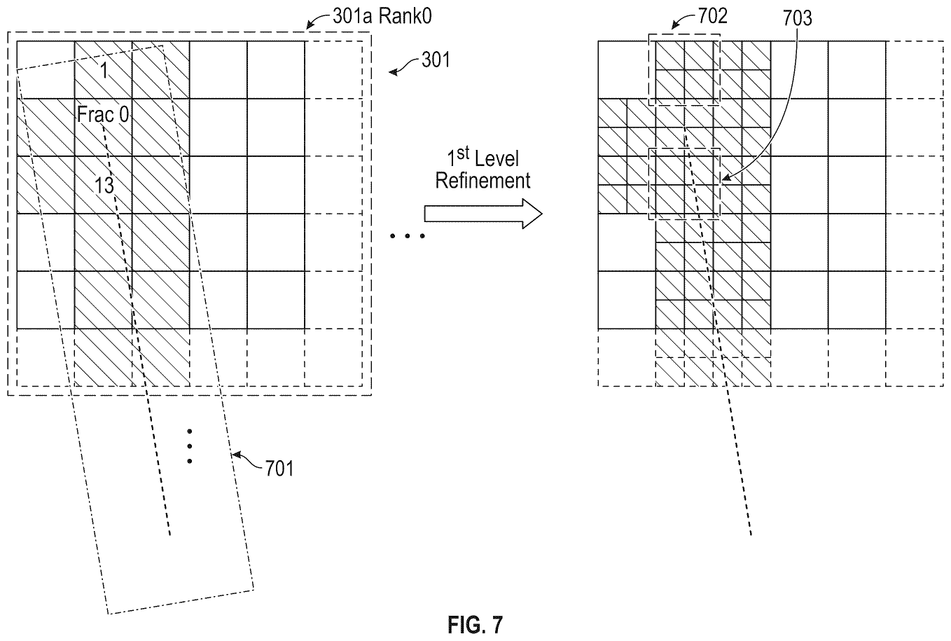

In Step 205, LGR is performed based on a user-defined refinement radius value. A cuboid is constructed from the fracture polygon and the refinement radius value, and the location of the center of each cell is compared with the cuboid. If the center of a particular cell lies within the cuboid, then that cell is marked for refinement at the current refinement level. In the example shown in FIG. 7, for frac 0, the blue dash-line box shows the cuboid (701) constructed from the fracture polygon and the refinement radius for the first level refinement. The highlighted cells whose cell centers lie within the cuboid (701) are selected and refined using a user-defined first level refinement factor, such as 2×2. For example, the highlighted cell 1 and cell 13 have their cell centers within the cuboid (701) and are selected for refinement into 2×2 refined grid blocks, (702) and (703), respectively.

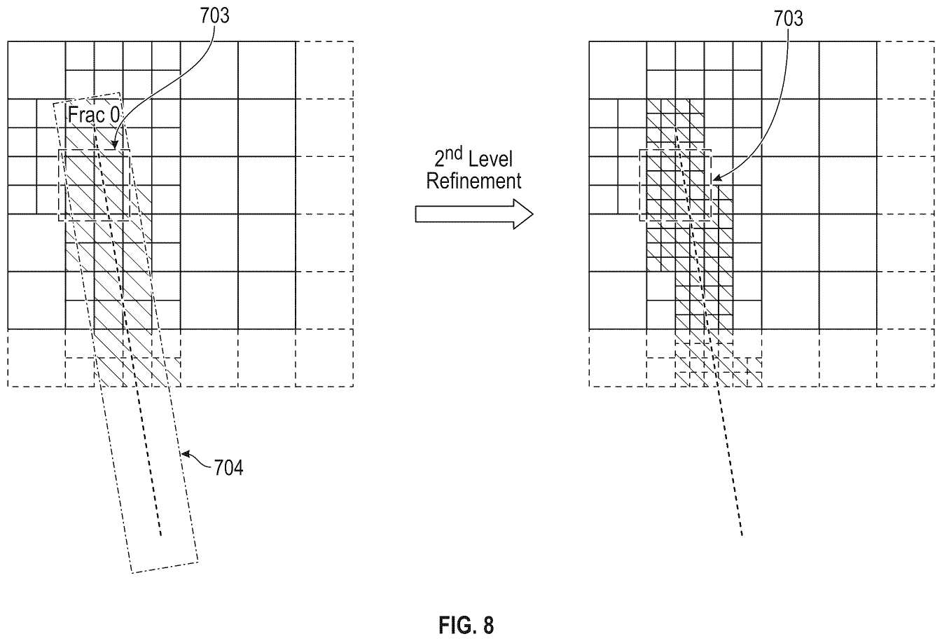

FIG. 8 shows the example for the next level of refinement where the refined 2×2 grids of all selected cells after the first level refinement are used as the basis for the second level refinement. A smaller cuboid (704) constructed from the fracture polygon and the second level refinement radius is used to select cells to be further refined. The selected cells are highlighted in FIG. 8 and are refined by a user-defined second level refinement factor that may be different from the first level refinement factor. For example, each of the 4 grid cells in the first level refined grid (703) is further refined into 2×2 second level refined grid blocks. As a result, the original grid cell 13 subdivides into 16 second level refined grid cells after the second level refinement. Once the LGR is completed for all refinement levels, the unstructured grid data is generated again based on the refined grid.

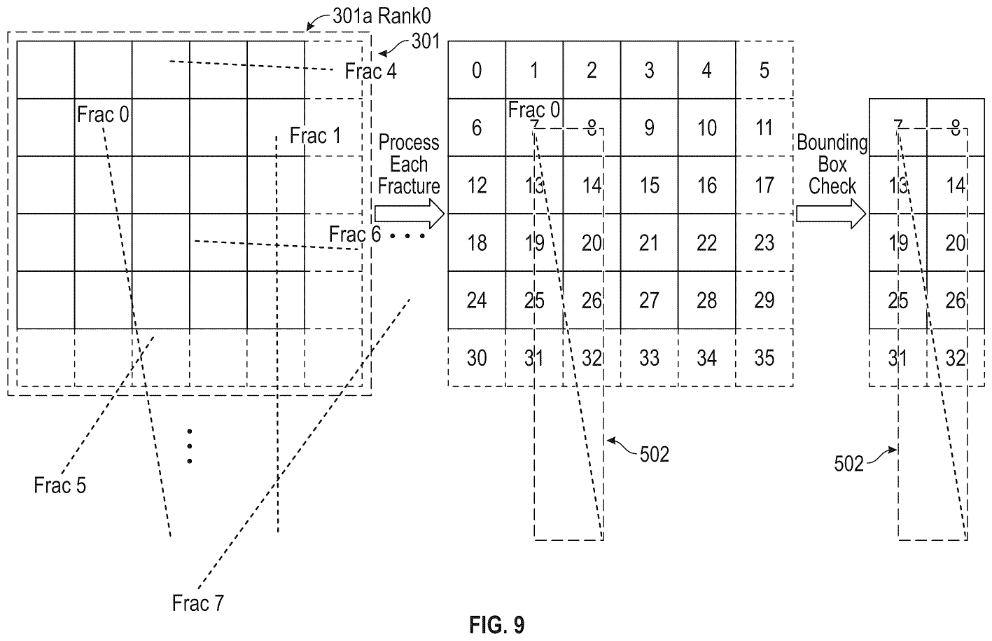

In Step 206, matrix cells (from either initial grid cells or refined grid cells) that may intersect with each local fracture are identified for each rank of the partitions. Within each rank, all matrix cells are checked against each local fracture to form a list for each local fracture, which includes matrix cells that potentially intersect with each local fracture. Two-dimensional bounding box intersection checks are first performed to filter the vertical columns of grid cells that may intersect with the fracture, and then each cell in the selected columns is tested for intersections with the fracture using 3D bounding box intersection checks. In the example in FIG. 9, within Rank 0 (301a), cells with local indices 7, 8, 13, 14, 19, 20, 25, 26, 31, 32 are marked as potential matrix cells that may intersect with Frac 0 as they intersect with the bounding box of Frac 0 (502). These cells are then directed for further detailed matrix-fracture intersection calculations, which are more accurate but also more computationally costly.

While Step 203 above involves checking for intersections between fractures and the bounding boxes of entire grid partitions, in order to determine the local fractures in each partition. In contrast, Step 206 involves checking for intersections between fractures and the bounding boxes of individual grid blocks within a partition, in order to narrow down the set of grid cells that need to be directed for more detailed matrix-fracture intersection calculations.

In Step 207, matrix-fracture intersections, fracture-fracture connections, and well-fracture intersections are checked and calculated in three sub-steps (i), (ii), and (iii). After these calculations, each input fracture has been discretized or otherwise divided into fracture cells by the boundaries of matrix cells. Some of these matrix cells may be refined grid cells if LGR is applied in Step 204 above.

Step 207 (i) conducts detailed matrix-fracture intersection calculations between each local input fracture and its potential intersecting matrix cells. The term “local” refers to being within the partition allocated to a particular CPU for processing. For each matrix cell to check, the intersection points of the cell and the infinite plane of the fracture polygon are calculated. The infinite plane is a mathematical 3D plane that contains the fracture polygon. It is then checked whether the cell-plane intersection (defined by the intersection points) has an overlap area with the input fracture polygon. The matrix-fracture intersection is the overlapping area of the fracture polygon and the cell-infinite plane intersection.

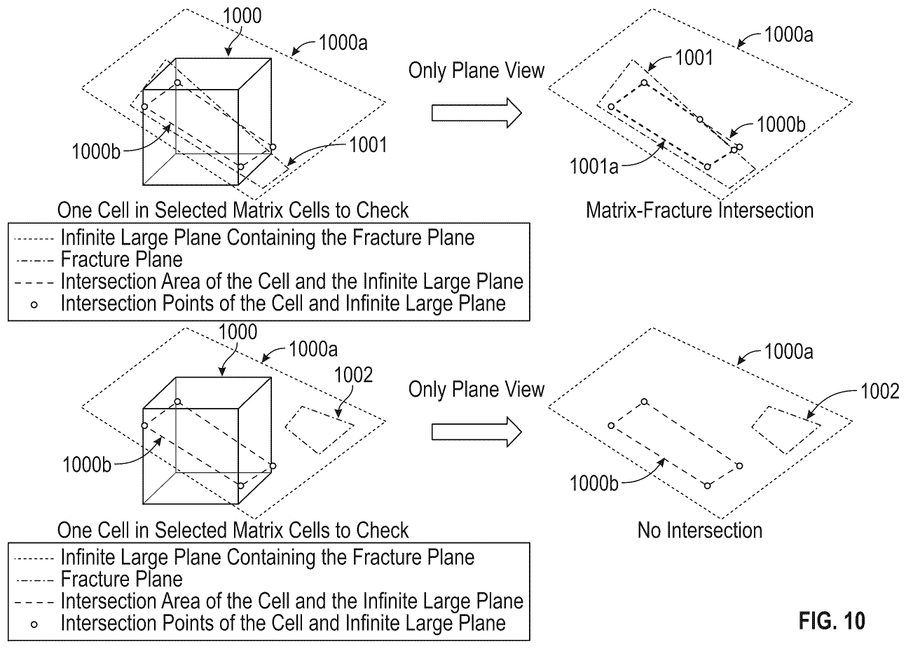

In the example in FIG. 10, the first input fracture polygon (1001) has an intersection area with the 3D cell (1000). The second input fracture polygon (1002) does not have an intersection area with the 3D cell (1000), since even though the infinite plane (1000a) it lies in has an intersection area (i.e., cell-infinite plane intersection (1000b)) with the 3D cell (1000), that intersection area (1000b) does not overlap the input fracture polygon (1002).

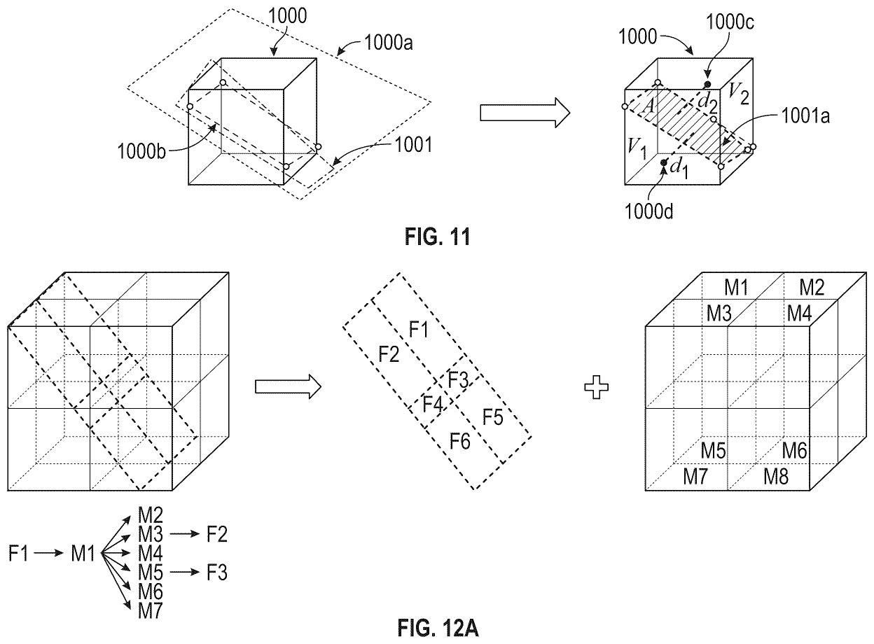

In contrast, a matrix-fracture intersection (1001a) (denoted as the dash-line polygon) exists between the first input fracture polygon (1001) and the cell-infinite plane intersection (1000b). In the context that the first input fracture polygon (1001) or the first input fracture (1001) is divided by intersecting 3D cells into respective matrix-fracture intersections, the matrix-fracture intersection (1001a) is referred to as a fracture cell of the 3D cell (1000). As shown in FIG. 11, the matrix-fracture intersection (1001a) divides the 3D cell (1000) into two partitions referred to as the matrix splits (V₁, V₂). Accordingly, the intersection area A of the matrix-fracture intersection (1001a), perpendicular distances (d₁, d₂) from the geometric centers (1000c, 1000d) of the two matrix cell splits (V₁, V₂) to the matrix-fracture intersection (1001a), volumes of the two matrix cell splits (V₁, V₂), aperture (upscaling if non-uniform input), and permeability (upscaling if non-uniform input) are calculated. Aperture (or width) is the thickness of the fracture opening. Aperture and permeability are part of the fracture geometry data input into the simulator.

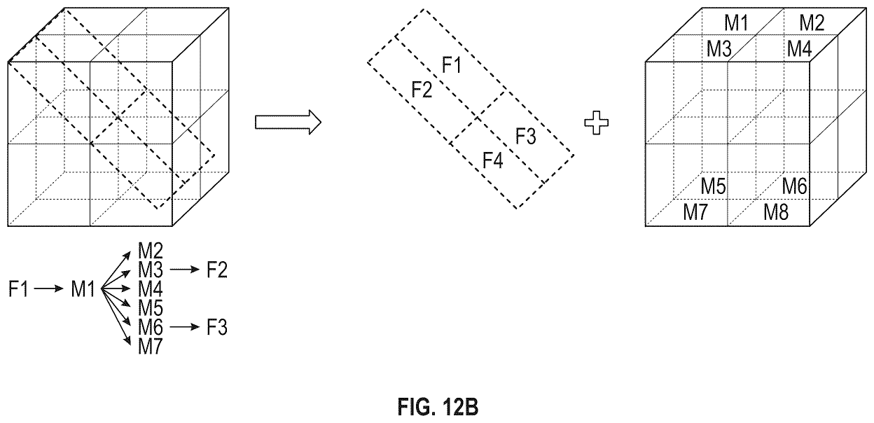

Step 207 (ii) checks for intra-fracture connections and inter-fracture connections. Intra-fracture connections are fracture-fracture connections (within the same fracture). Intra-fracture connections are checked by checking the connection on matrix cells:
(a) For each fracture cell within a fracture, find its matrix cell in the 3D refined grid.
(b) Find matrix cell neighbors of the matrix cell found in (a) (both face and edge neighbors from the unstructured grid data built in the previous steps).
(c) Check if there exists other fracture cells from the same input fracture in the neighboring matrix cells. If there are such fracture cells, calculate the shared edges between the two fracture cells to find the connected fracture cells within one input fracture. In the first example in FIG. 12A, fracture cell F1 lies in matrix cell M1, which has face neighbors M2, M3, M5 and edge neighbors M4, M6, M7. Each of these neighbor matrix cells are checked to see if they contain any fracture cells that belong to the same fracture as F1. This check identifies that fracture cell neighbors F2 and F3 in the face neighbor cells M3 and M5, respectively, belong to the same fracture as F1. In other words, intra-fracture connections exist between F1, F2, and F3 in M1, M3, and M5, respectively. In the second example in FIG. 12B, intra-fracture connections exist between F1 and F2 via face neighbor adjacency and between F1 and F3 via edge neighbor adjacency.

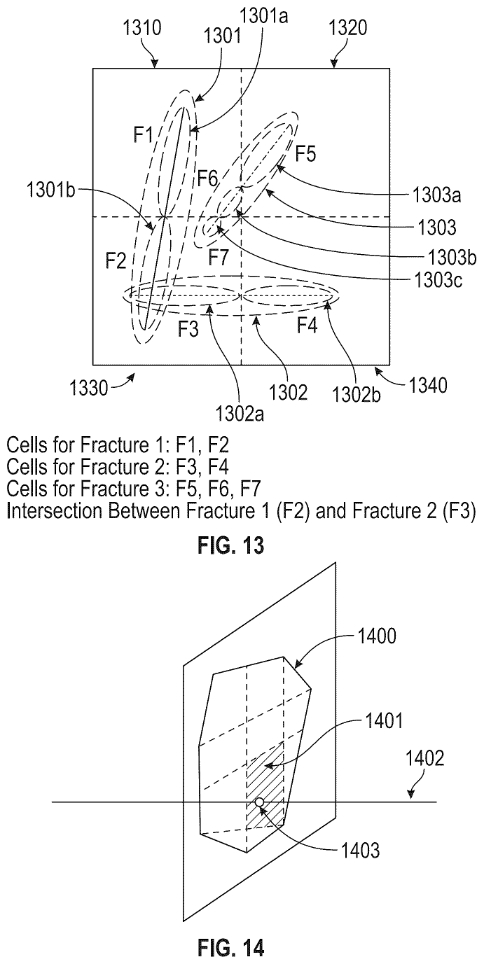

In contrast to intra-fracture connections, the inter-fracture connections are fracture-fracture intersections (between different fractures) within the same matrix cell. Inter-fracture connections are identified by checking the connections within matrix grid cells:
(a) For a fracture cell within a fracture plane, find its intersecting grid cell in the 3D refined grid.
(b) Find all fracture cells (from other fracture planes) within the grid cell.
(c) Check if two fractures are intersecting to identify a fracture polygon-fracture polygon intersection. For example, in the example in FIG. 13 depicting matrix cells (1310, 1320, 1330, 1340), the fracture cells are represented as line segments, such as F1 (1301a) and F2 (1301b) of the fracture 1 polygon (1301), as well as F3 (1302a) and F4 (1302b) of the fracture 2 polygon (1302), as well as F5 (1303a), F6 (1303b), and F7 (1303c) of the fracture 3 polygon (1303). In the top left matrix cell (1310), there are fracture cells F1 (1301a) and F6 (1303b), but they do not have an intersection. In the bottom left matrix cell (1330), there are fracture cells F2 (1301b), F3 (1302a), F7 (1303c) with an intersection between F2 (1301b) and F3 (1302a) indicating that there is an intersection between the fracture 1 polygon (1301) and the fracture 2 polygon (1302). Then the connection between F2 (1301b) and F3 (1302a) is recorded and added as an inter-continua connection within the same grid cell (1330) to be used in the later steps.

Step 207 (c) calculates well-fracture intersections to determine perforation locations. The well trajectories are input as a list of 3D points and these recorded points form line segments that represent the well trajectories. Firstly, the well trajectories that exist locally in the partition are calculated. This is done by comparing the bounding box of each line segment (representing a well trajectory) with the bounding box of the grid in the partition. Then for each fracture cell, a line segment-polygon intersection calculation is performed to find out the intersection between the line segment of a well and a fracture cell. The intersection point is the perforation location of the well on the corresponding fracture and the fracture geometry is used to calculate the productivity index on this perforation. For example, in FIG. 14, one fracture polygon (1400) is discretized into 11 fracture cells, such as fracture cell (1401). Through calculation, the well segment represented by the straight-line segment (1402) intersects the fracture cell (1401), and the intersection point (1403) is marked as the perforation location.

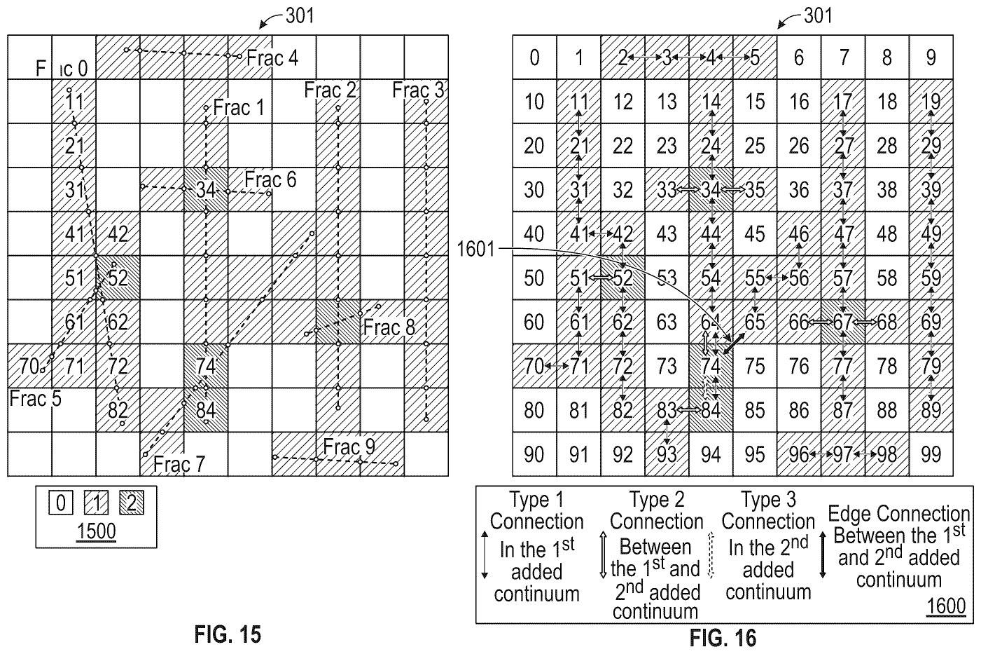

In Step 208, extra continua are calculated to set up an MPMP data structure. Each extra continuum is a collection of extra continuum grid cells that superimposes the matrix grid. In this context, the extra continuum is referred to as a continuum grid where each matrix cell of the matrix grid contains continuum cells of the continuum grids. After each input fracture has been discretized into fracture cells by the boundaries of matrix cells in Step 207, the number of fracture cells within each matrix cell is counted. Extra continua needed to store or otherwise hold the fracture cells are calculated. The number of extra continua is equal to the maximum number of fracture cells within each matrix cell. In the example (without considering local grid refinement) shown in FIG. 15, the discretized fracture cells are denoted as line segments delimited by matrix cell boundaries and the number of fracture cells per matrix cell is depicted according to the legend (1500). For example, the fracture cells of Frac 0 are within matrix cells 11, 21, 31, 41, 42, 52, 62, 72, and 82, while the fracture cells of Frac 5 are within matrix cells 52, 51, 61, 71, and 70. Because the matrix cell 52 holds (i.e., geometrically contains) fracture cells for both Frac 0 and Frac 5, the number of fracture cells per matrix cell is 2 for the matrix cell 52. In the example shown in FIG. 15, the number of extra continua needed to store data for the fracture cells is 2.

To set up the MPMP data structure, the matrix grid is extended to include the extra number of continua. In other words, the simulation grid now includes the matrix grid and the extended continua. In contrast to the conventional EDFM that extends the original grid by appending fracture cells on the side and uses special non-neighbor connection functionalities provided by the reservoir simulator to represent the F-F and F-M connections, each of the additional or extra continua constructed in Step 208 corresponds to a copy of the grid (e.g., grid (301)) mathematically superimposed over the matrix grid. The porosity, permeability, etc. of each newly added continuum are initialized to 0. In the scenario where the simulation grid includes one matrix grid as an initial continuum (e.g., a single porosity single permeability model), the number of continua becomes 3 after adding the 2 extra continua as illustrated in FIG. 15. In the gridded reservoir model with single porosity and single permeability, the initial continuum 0 is the matrix grid that stores information (e.g., rock properties) regarding the matrix and is referred to as the matrix continuum while continua 1 and 2 are superimposed grids that store information regarding the fractures and are referred to as fracture continua.

Accordingly, the fracture cells are assigned or distributed into the extra continua, e.g., based on the global indices of the input fractures. In the example shown in FIG. 16, matrix cells stay in continuum 0, and all fracture cells belonging to Frac 0 are distributed into continuum 1. All fracture cells belonging to Frac 5 are also distributed into continuum 1 except for the fracture cell that lies in matrix cell 52, which is distributed into continuum 2. This is because continuum 1 of grid cell 52 is already occupied by the fracture cell of Frac 0. Distributing a fracture cell into a continuum refers to storing the fracture cell, or more specifically, the geometric data and properties (e.g., porosity, permeability) of the fracture cell in a corresponding continuum cell of the assigned continuum. For example, the geometric data of the fracture cell may include intersection area of the matrix-fracture intersection, distances from the geometric centers of the two matrix cell splits to the matrix-fracture intersection area, volumes of the two matrix cell splits, etc. that are calculated in Step 207 above.

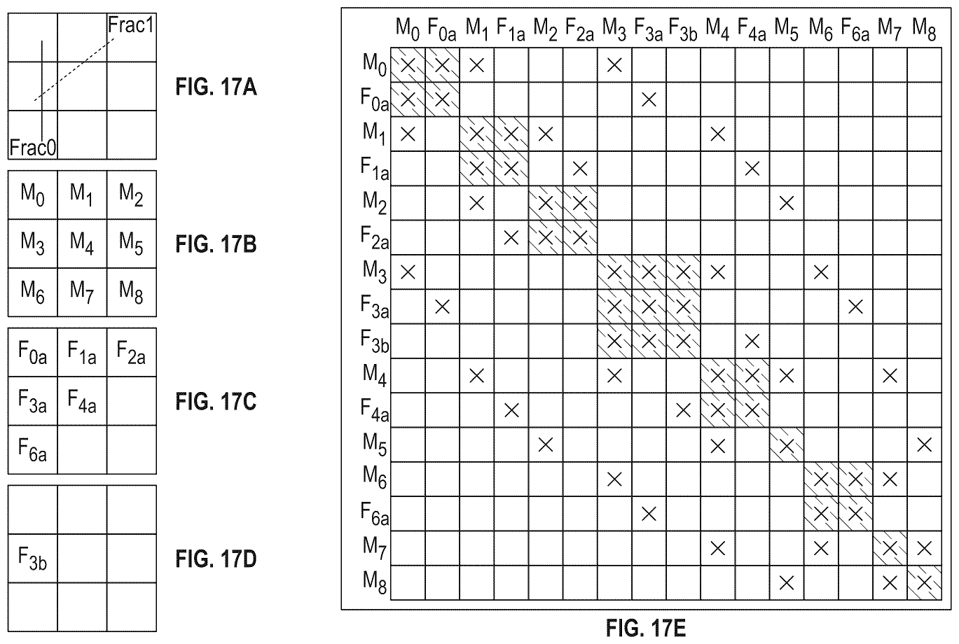

FIG. 17A-17E show a simple illustration, a 3×3 grid block example with 2 fractures (Frac0, Frac1) is shown in FIG. 17A. The matrix cells (M0-M8) are shown in FIG. 17B. After EDFM/MPMP calculation, the two fractures are discretized by the grid blocks into fracture cells (F0a, F1a, F2a, F3a, F4a, F6a, F3b) and two extra continua (where subscript a and b on the fracture cell labels indicate the extra continua a and b) are added to place the extra fracture cells, as shown in FIG. 17C and FIG. 17D.

Using a simpler 3×3 case with two input fractures Frac0 and Frac1, the extra number of continua needed is 2 and when forming the system of equations, a 9×9 matrix is formed as shown in FIG. 17E. Nine composite blocks correspond to each grid block are considered and each composite block contains the matrix cell and the fracture cells (if any). Within each highlighted composite block, the diagonal terms represent the accumulation of the matrix cell or the fracture cells (if any) and the off-diagonal terms represent the flux between the matrix cell and fracture cell with in the same grid block (if any). The unhighlighted off-diagonal terms represent the flux between neighbors within each individual continuum.

In Step 209, matrix-fracture connections, fracture-fracture connections, and transmissibility are established in the MPMP data structure.

For the matrix-fracture and fracture-fracture connections, a set of connection data between the matrix cells and fracture cells, and between the fracture cells and fracture cells are generated:
(a) First, each fracture cell in the extra continua is connected to the matrix cell in the corresponding (i.e., superimposed) location. This constructs the matrix-fracture connections.
(b) Next, fracture cell-fracture cell connections within the same input fracture are constructed. This type of connection exists between fracture cells assigned to two different matrix grid cells that are face neighbors or edge neighbors of each other, such as the connection (1601) between matrix cells 65 and 74 shown in FIG. 16.
(c) As the last step, the connections between fracture cells belonging to different input fractures (fracture intersections) are identified. This type of connection exists between fracture cells that lie within the same grid cell. For example, the two fracture cells in the first added continuum (i.e., continuum 1) and the second added continuum (i.e., continuum 2) of the grid cell 34 have a connection because they represent the fracture-fracture intersection between frac 1 and frac 6. Specifically, the line segments representing the fracture cells of frac 1 and frac 6 physically intersect each other within the grid cell 34. Similarly, the two fracture cells in the first added continuum (i.e., continuum 1) and the second added continuum (i.e., continuum 2) of the grid cell 74 also have a connection. An opposite scenario would be the two fracture cells in the two extra continua in grid cell 84. Although they are within the same grid cell, the line segments representing the fracture cells of frac 1 and frac 7 do not physically intersect each other within the grid cell 84. Therefore, no connection is established between the fracture cells represented by the two extra continua in grid cell 84.

The connections established in (a) are not explicitly shown in FIG. 16. Different connections established in (b) and (c) are represented by arrows according to the legend (1600).

As shown in FIG. 16, type 2 connections and edge connections are not regular connections defined in traditional MPMP system. The edge connection represents a connection crossing edge neighbor cells of different continua and the type 2 connection represents a connection crossing face neighbor cells of different continua.

The calculated perforations (grid cell I, J, K coordinates, continuum indices) and productivity indices (PI) described in reference to FIG. 1B above are added to the corresponding wells to be used for source/sink terms when operating the wells. In particular, perforation and PI calculation are separate from transmissibility calculation and MPMP setup.

Special treatment when calculating the transmissibility of the MPMP system includes using the calculated F-M and F-F connectivity and transmissibility instead of the traditional method in MPMP model. The matrix-fracture and fracture-fracture transmissibility can be calculated as shown in the following two equations. Variables contained in the following equations are defined in TABLE 2 below.

$${T}_{f - m} = \frac{2 {A}_{f} \vec{n} \cdot ( \vec{\vec{K}} \cdot \vec{n} )}{( {V}_{A} {d}_{1} + {V}_{B} {d}_{2} ) / ( {V}_{A} + {V}_{B} )} \qquad ( 1 )$$

$${T}_{f - f} = \frac{1}{\frac{{d}_{1}}{{K}_{f 1} {A}_{f}} + \frac{{d}_{2}}{{K}_{f 2} {A}_{f}}} \qquad ( 2 )$$

In the traditional MPMP method, the matrix-fracture transmissibility is calculated by inputting shape factor or geometry coefficient. For the shape factor option,

$${T}_{f - m} = V \cdot σ \cdot {k}_{x}$$

For the geometry option,

$${T}_{f - m} = 4 V ( \frac{{k}_{x}}{{L}_{x}^{2}} + \frac{{k}_{y}}{{L}_{y}^{2}} + \frac{{k}_{z}}{{L}_{Z}^{2}} )$$

The fracture-fracture transmissibility in traditional MPMP method is same as matrix-matrix transmissibility calculation but with fracture permeability.

$${T}_{f - f} = \frac{{A}_{m}}{\frac{{d}_{1 m}}{\vec{{n}_{1 m}} \cdot ( \vec{\vec{{K}_{f 1}}} \cdot \vec{{n}_{1 m}} )} + \frac{{d}_{2 m}}{\vec{{n}_{2 m}} \cdot ( \vec{\vec{{K}_{f 2}}} \cdot \vec{{n}_{2 m}} )}}$$

As illustrated above, the matrix-fracture, fracture-fracture transmissibility calculation is grid dependent in the traditional MPMP method.

TABLE 2

| | |
|---|---|
| Aₘ | Cross-section area between two adjacent grid blocks |
| d₁ₘ, d₂ₘ | Distances from the grid block centers to cross-section between two adjacent grid |
| | blocks |
| A_{f} | Cross-section area of matrix-fracture or fracture-fracture intersection |
| d₁, d₂ | Distance from the centers of the matrix/fracture or fracture/fracture to the cross- |
| | section |
| I₁, J₁, K₁ | I, J, K indices for the first cell in one non-neighbor connection cell pair |
| I₂, J₂, K₂ | I, J, K indices for the second cell in one non-neighbor connection cell pair |
| [symbol] | Permeability tensor |
| [symbol] , [symbol] | Permeability tensor of fracture cells |
| [symbol] | Normal vector to the cross-section of the matrix-fracture intersection |
| [symbol] , [symbol] | Normal vector to the cross-section between two grid blocks |
| T_{f-f} | Transmissibility between the fracture-fracture intersection |
| T_{f-m} | Transmissibility between the matrix-fracture intersection |
| V_{A}, V_{B} | Volumes of the two parts of a matrix cell split by a fracture plane |
| V | Volume of the grid cell |
| σ | Mass transfer coefficient |
| kₓ, k_{y}, k_{z} | Matrix permeability |
| Lₓ, L_{y}, L_{z} | Typical X, Y, Z dimensions of the blocks of materials making up the matrix |
| | volume |

In Step 210, the reservoir simulator starts time stepping based on the MPMP data structure established above to generate simulation result at each time step. For example, the MPMP data structure may include the matrix grid with stored rock properties, the continuum grid with stored fracture cell geometry data, the matrix-fracture connections, and the fracture-fracture connections. In one or more embodiments, the matrix-fracture connections and the fracture-fracture connections are stored in corresponding matrix cells and/or continuum cells. In Step 211, the reservoir simulation result is completed for the time period specified for the simulation.

In Step 212, a field operation is performed based on the reservoir simulation result. For example, the reservoir simulation may be performed for each of a large number (e.g., 1000) wells of the reservoir to generate the reservoir simulation result. Such simulation result of these large number (e.g., 1000) of wells of the reservoir may be used to facilitate the well production operations of the entire reservoir.

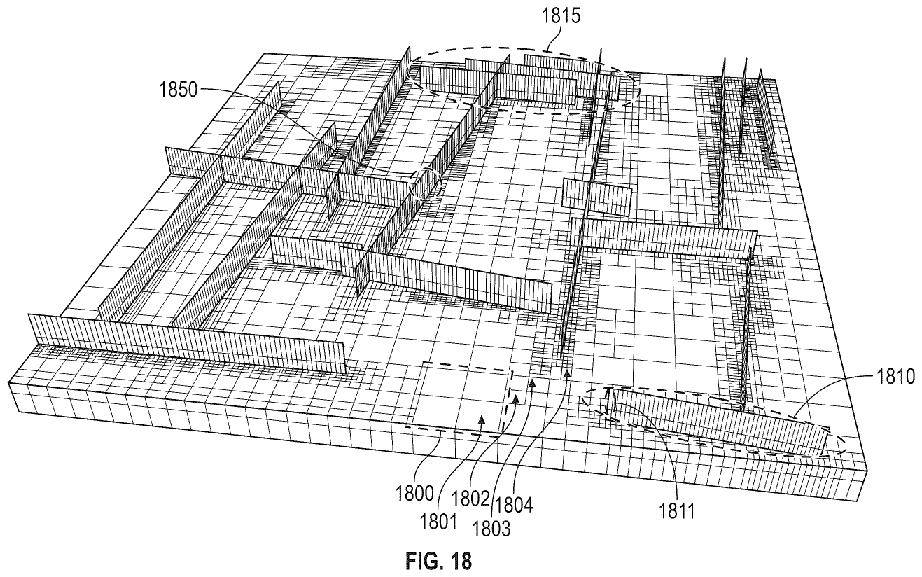

FIGS. 18-21 show an implementation example in accordance with one or more embodiments. In particular, FIGS. 18-21 illustrate using the EDFM/MPMP modeling engine to facilitate reservoir simulation for a local grid refinement example.

This example considers a 10×10×3 structured grid containing one perforation (1850) and 20 fractures (e.g., fracture (1810, 1815)) where one single layer of 10×10×1 grid cells (e.g., grid cell (1800)) is shown in FIG. 18. Each grid cell before local grid refinement has a dimension of 100 ft×100 ft×20 ft. Four nested levels of local grid refinement are illustrated using the EDFM/MPMP modeling engine to perform the workflow depicted in FIG. 2 above. The refinement radii for the refinement levels are set to be 200 ft, 100 ft, 50 ft and 25 ft for the different levels, respectively. For example, the grid cell (1801) is a first level refined grid cell, the grid cell (1802) is a second level refined grid cell, the grid cell (1803) is a third level refined grid cell, and the grid cell (1804) is a fourth level refined grid cell. Each of the 20 fractures (e.g., fracture (1810)) is discretized into fracture cells (e.g., fracture cell (1811)) within corresponding fourth level grid cells. During the local grid refinement, 300 first level refined grid cells, 846 second level refined grid cells, 1845 third level refined grid cell and 3849 fourth level refined grid cells are added while 4030 fracture cells are constructed. In addition, 39 fracture-fracture intersections and 6662 fracture-fracture connections are detected where 2 extra continua are constructed to store the fracture cells in the MPMP data structure.

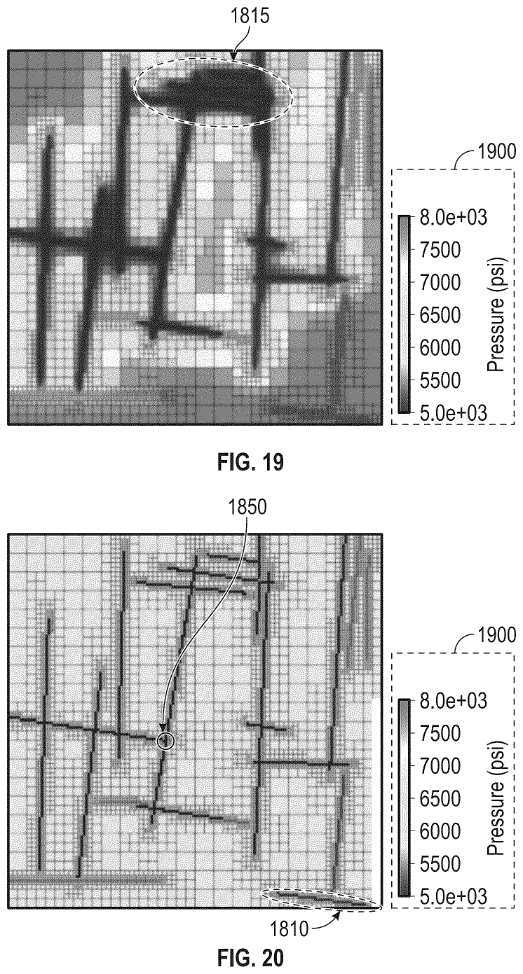

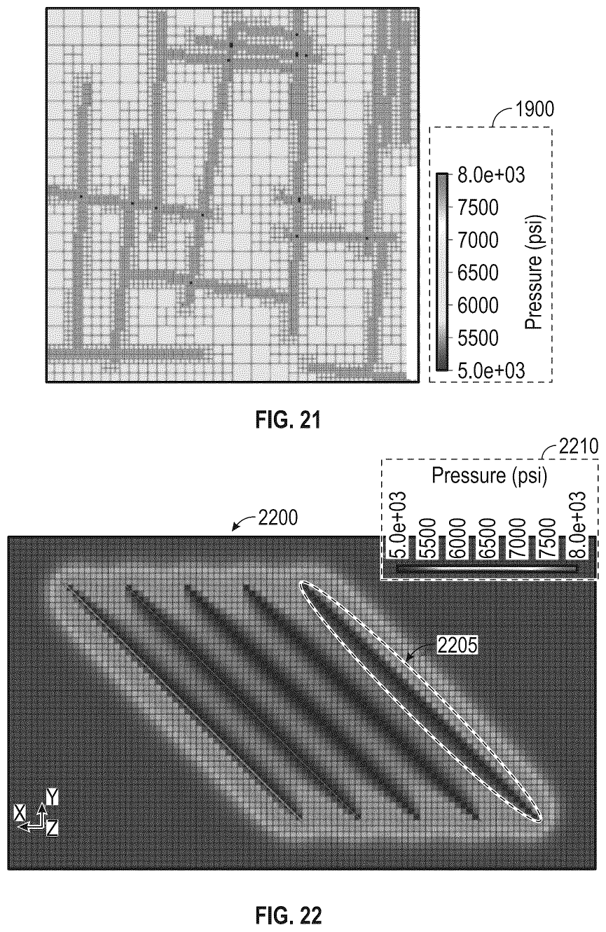

The depletion through the fracture is simulated based on the MPMP data structure to generate the pressure distribution in the matrix continuum and the two added fracture continua as shown according to the legend (1900) in FIG. 19, FIG. 20, and FIG. 21, respectively. FIG. 19 shows pressure distribution in the matrix continuum where the pressure drop (e.g., reduced from 8000 psi to 5000 psi) mostly occurs in the near fracture region, such as near the fracture (1815). FIG. 20 shows pressure distribution of fracture cells stored in the first extra continuum where only the fractures that are directly connected to the perforation (1850) or connected to the perforation (1850) through other fractures show significant pressure drops. For example, the fracture (1810) is not connected directly or indirectly to the perforation (1850) and therefore the region near the fracture (1810) does not show pressure drop from 8000 psi. Disconnected fractures have very small pressure drops, which mostly happens because of the connection through the matrix. FIG. 21 shows pressure distribution of intersection fracture cells (i.e., with two or more fracture cells within one matrix grid cell) stored in the second extra continuum.

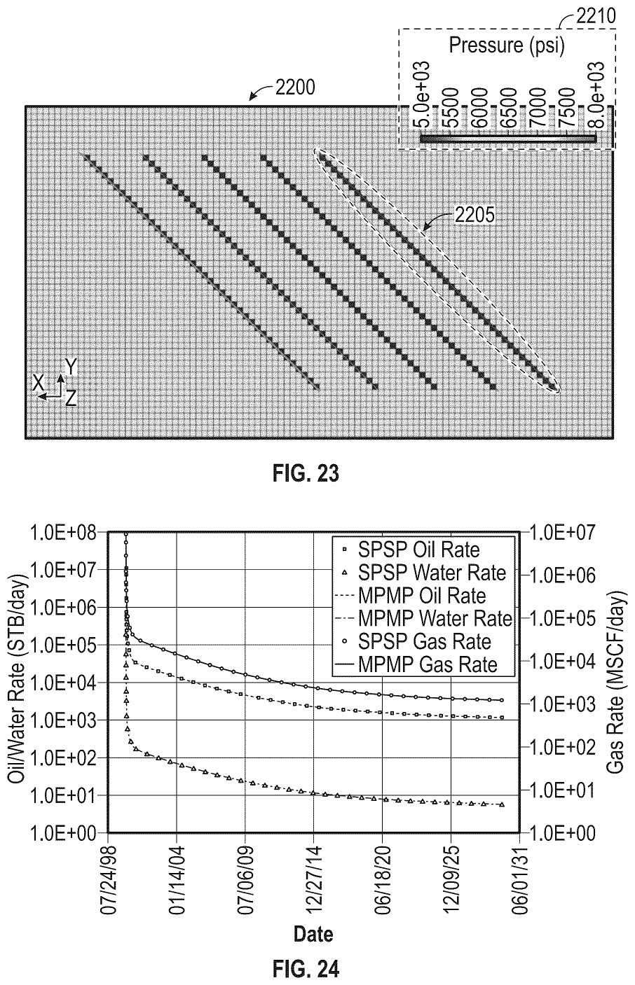

FIGS. 22-23 show an implementation example in accordance with one or more embodiments. In particular, FIGS. 18-21 illustrate using the EDFM/MPMP modeling engine to facilitate reservoir simulation for a local edge neighbor connection case. In this example, the treatment of hydraulic fractures intersecting matrix cells via edge-neighbor connections in a 100×100×1 grid (2200) is illustrated. Specifically, five fractures (e.g., fracture (2205)) oriented 45 degrees between the X and Y axes are inputted to the EDFM/MPMP modeling engine and processed. The model requires only one extra continuum to store the fracture cells. The initial pressure is 8000 psi in the matrix, and the production pressure is 5000 psi at the perforation locations (in the middle of each fracture). Twenty-five computer processors (i.e., CPUs) are used to compute the EDFM/MPMP model and perform the reservoir simulation. FIG. 22 shows a pressure distribution of depletion in the matrix through the fractures according to legend (2210). Significant pressure drops are observed in the near fracture region. FIG. 23 shows the pressure distribution (i.e., fracture pressure in the fracture cells) in the added continuum which are equivalent to the production pressure. This demonstrates that the EDFM/MPMP model correctly represents the local edge neighbor connections.

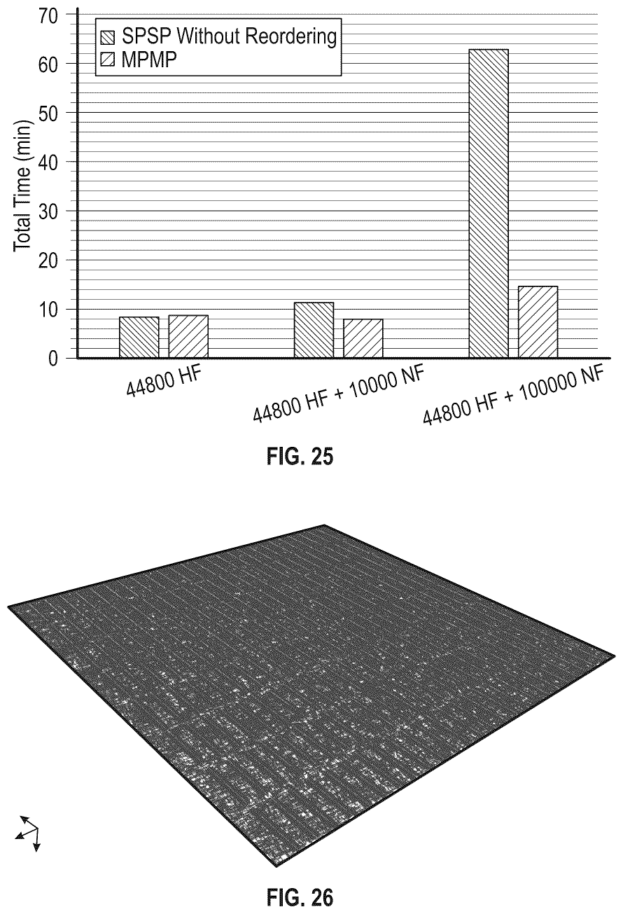

FIGS. 24 and 25 illustrate performance comparison with traditional EDFM. In particular, the results and performance of the EDFM/MPMP modeling engine and associated method workflow is compared with traditional EDFM on three different variations of a complex model. The model consists of a 528×528×11 structured grid with 3,066,624 matrix cells. There are 400 wells, with each well containing 112 hydraulic fractures, which results in a total of 44,800 hydraulic fractures (HFs) in the entire model. In addition to the hydraulic fractures, the three case variations have 0, 10000, and 100000 natural fractures (NFs) respectively. FIG. 24 shows comparison of oil, gas, water production rates for the 400-well case with 44800 hydraulic fractures using the conventional single porosity-single permeability (SPSP) method and MPMP method using the EDFM/MPMP modeling engine described above. FIG. 25 shows computer run time comparison for generating the EDFM/MPMP model and simulating the reservoir of the three cases: 44800 HF, 44800 HF+10000 NF, and 44800 HF+100000 NF. While the simulation results are identical, the computing time of the traditional SPSP approach using the conventional EDFM is outperformed by the EDFM/MPMP approach where fracture cells are inherently stored in a more organized format based on the matrix grid. When the MPMP approach is used, the strong matrix-fracture connections appear on the diagonal blocks of the Jacobian matrix, making the matrix more diagonally dominant (FIG. 17). The EDFM/MPMP modeling engine combines the matrix and fracture cells in each grid block into a single composite cell. Increased diagonal dominance improves the convergence behavior of conventional smoother-based preconditioners, leading to much better linear solver performance. This leads to much better grid partition and linear solver performance.

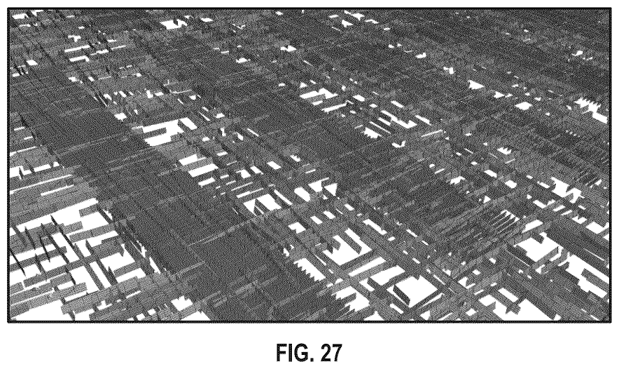

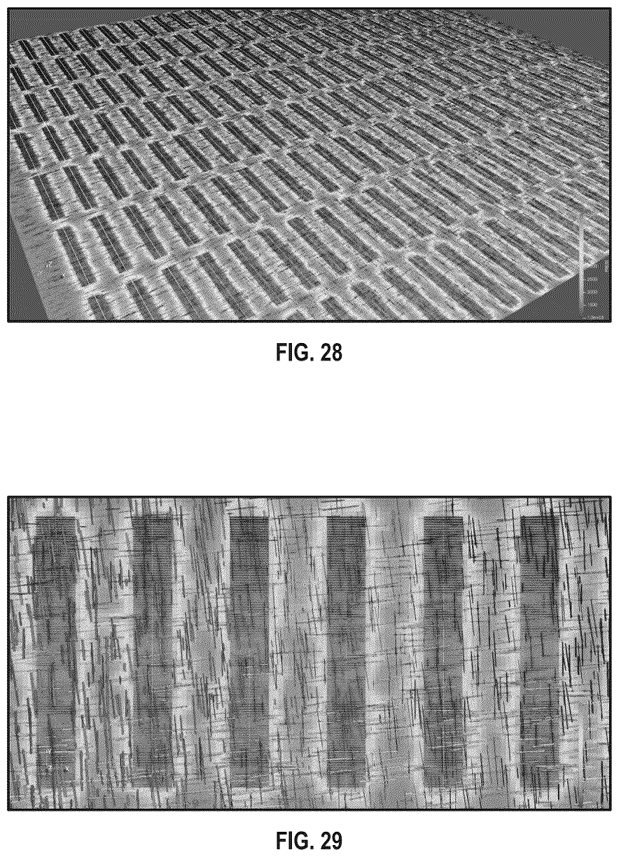

The scaling test of the intersection calculation in parallel using a very complex case shows negligible processing time and good scaling when using more CPUs. The calculation leads to 5507541 discretized fracture cells, 1885790 fracture-fracture intersections, 9198648 fracture-fracture connection, 58340 well-fracture connection (perforations) and 12 extra continua. FIG. 26 shows the discretized fracture networks of which a portion is enlarged and shown in FIG. 27. FIG. 28 shows the EDFM/MPMP modeling engine generated pressure distribution of which a portion is enlarged and shown in FIG. 29.

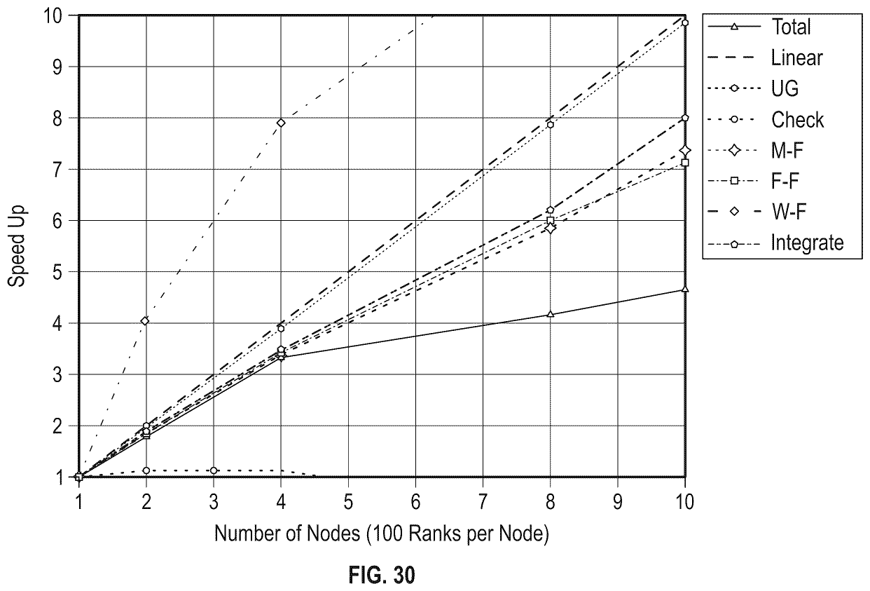

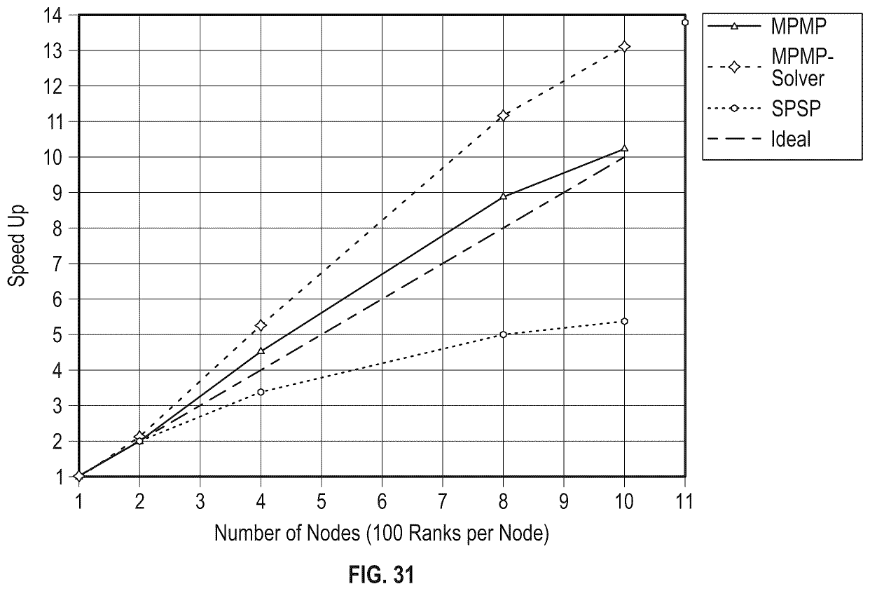

The breakdown of the total time taken to setup the MPMP system is shown in TABLE 3. The strong scaling plot (using results from 1 node as the reference) given in FIG. 30 shows that most components of the EDFM/MPMP modeling engine workflow exhibit a decent speedup as the number of parallel processes is increased. The part that caused the scaling to be not ideal is the potential intersection check part, which includes all-to-all MPI communication and because each rank must process all the fracture data, the cell check part is not scalable. If this case is run in serial, the total processing time is over 10 hours. In addition, the scalability test results of the full simulation using the new MPMP method and traditional SPSP method is shown in FIG. 31. The MPMP simulation shows superior linear scaling with better solver performance by improving data locality, caching, and reducing the bandwidth of the resulting linear system. Meanwhile the SPSP extended grid simulation shows poor scalability. It is also worth noting that in the tests the SPSP extended grid simulation shows memory constraint using only 1 node, so the starting point for SPSP extended grid simulation is 2 nodes.

TABLE 3

| | | Time (s) | | | | | | |
|---|---|---|---|---|---|---|---|---|
| | | | Fracture | | | | | |
| | | | distribution | | | | | |
| | | Unstructured | and potential | Matrix- | Fracture- | Well- | Integration | |
| | | grid | intersection | fracture | fracture | fracture | into MPMP | |
| Number | Number | construction | check | intersection | intersection | intersection | system | |
| of nodes | of CPUs | (UG) | (Check) | (M-F) | (F-F) | (W-F) | (Integrate) | Total |
| 1 | 100 | 0.275 | 0.149 | 2.05 | 0.287 | 0.312 | 0.3065 | 3.3795 |
| 2 | 200 | 0.137 | 0.13 | 1.13 | 0.158 | 0.0763 | 0.161 | 1.7923 |
| 4 | 400 | 0.0708 | 0.129 | 0.602 | 0.0837 | 0.0396 | 0.0879 | 1.013 |
| 8 | 800 | 0.0348 | 0.299 | 0.349 | 0.0478 | 0.027 | 0.0494 | 0.807 |
| 10 | 1000 | 0.0279 | 0.314 | 0.278 | 0.0403 | 0.0238 | 0.0382 | 0.7222 |

Embodiments have the following advantages regarding efficiency, accuracy, and ease of use within a parallel reservoir simulator.
(1) The fracture geometry can be accurately represented.
(2) The fracture geometry data can be processed using a large number (e.g., thousands) of CPUs to greatly speed up the intersection calculation, such as reducing the time from a few hours to less than one second.
(3) Additional inputs compared to a standard reservoir simulation only include the fracture geometry data and well trajectory data.
(4) The fracture intersection calculations are directly integrated with the main reservoir simulation. There is no need to transfer files or modify the input decks as is with traditional EDFM.
(5) The existing MPMP framework in a parallel reservoir simulator is used rather than using an extended grid in a single porosity-single permeability (SPSP) system with non-neighbor connections (NNC) representing the matrix-fracture and fracture-fracture connections. The workflow transforms the non-neighbor connections (NNCs) into regular face/edge neighbor connections or connections between different continua of the same grid cell. This greatly improves the quality of the parallel grid partitioning and provides better solver performance by improving data locality and reducing the bandwidth of the resulting linear system.
(6) Improved visualization options of the simulated results since matrix and fracture cells appear in the same spatial location but under different continua. The output of the extended grids required by traditional EDFM is avoided.

Embodiments may be implemented on a computer system. FIG. 32 is a block diagram of a computer system (3202) used to provide computational functionalities associated with described algorithms, methods, functions, processes, flows, and procedures as described in the instant disclosure, according to an implementation. The illustrated computer (3202) is intended to encompass any computing device such as a high-performance computing (HPC) device, a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (3202) may include a computer that includes an input device, such as a keypad, keyboard, touch screen, or other device that can accept user information, and an output device that conveys information associated with the operation of the computer (3202), including digital data, visual, or audio information (or a combination of information), or a GUI.

The computer (3202) can serve in a role as a client, network component, a server, a database or other persistency, or any other component (or a combination of roles) of a computer system for performing the subject matter described in the instant disclosure. The illustrated computer (3202) is communicably coupled with a network (3230). In some implementations, one or more components of the computer (3202) may be configured to operate within environments, including cloud-computing-based, local, global, or other environment (or a combination of environments).

At a high level, the computer (3202) is an electronic computing device operable to receive, transmit, process, store, or manage data and information associated with the described subject matter. According to some implementations, the computer (3202) may also include or be communicably coupled with an application server, e-mail server, web server, caching server, streaming data server, business intelligence (BI) server, or other server (or a combination of servers).

The computer (3202) can receive requests over network (3230) from a client application (for example, executing on another computer (3202)) and responding to the received requests by processing the said requests in an appropriate software application. In addition, requests may also be sent to the computer (3202) from internal users (for example, from a command console or by other appropriate access method), external or third-parties, other automated applications, as well as any other appropriate entities, individuals, systems, or computers.

Each of the components of the computer (3202) can communicate using a system bus (3203). In some implementations, any or all of the components of the computer (3202), both hardware or software (or a combination of hardware and software), may interface with each other or the interface (3204) (or a combination of both) over the system bus (3203) using an application programming interface (API) (3212) or a service layer (3213) (or a combination of the API (3212) and service layer (3213). The API (3212) may include specifications for routines, data structures, and object classes. The API (3212) may be either computer-language independent or dependent and refer to a complete interface, a single function, or even a set of APIs. The service layer (3213) provides software services to the computer (3202) or other components (whether or not illustrated) that are communicably coupled to the computer (3202). The functionality of the computer (3202) may be accessible for all service consumers using this service layer. Software services, such as those provided by the service layer (3213), provide reusable, defined business functionalities through a defined interface. For example, the interface may be software written in JAVA, C++, or other suitable language providing data in extensible markup language (XML) format or other suitable format. While illustrated as an integrated component of the computer (3202), alternative implementations may illustrate the API (3212) or the service layer (3213) as stand-alone components in relation to other components of the computer (3202) or other components (whether or not illustrated) that are communicably coupled to the computer (3202). Moreover, any or all parts of the API (3212) or the service layer (3213) may be implemented as child or sub-modules of another software module, enterprise application, or hardware module without departing from the scope of this disclosure.

The computer (3202) includes an interface (3204). Although illustrated as a single interface (3204) in FIG. 32, two or more interfaces (3204) may be used according to particular needs, desires, or particular implementations of the computer (3202). The interface (3204) is used by the computer (3202) for communicating with other systems in a distributed environment that are connected to the network (3230). Generally, the interface (3204) includes logic encoded in software or hardware (or a combination of software and hardware) and operable to communicate with the network (3230). More specifically, the interface (3204) may include software supporting one or more communication protocols associated with communications such that the network (3230) or interface's hardware is operable to communicate physical signals within and outside of the illustrated computer (3202).

The computer (3202) includes at least one computer processor (3205). Although illustrated as a single computer processor (3205) in FIG. 32, two or more processors may be used according to particular needs, desires, or particular implementations of the computer (3202). Generally, the computer processor (3205) executes instructions and manipulates data to perform the operations of the computer (3202) and any algorithms, methods, functions, processes, flows, and procedures as described in the instant disclosure.

The computer (3202) also includes a memory (3206) that holds data for the computer (3202) or other components (or a combination of both) that can be connected to the network (3230). For example, memory (3206) can be a database storing data consistent with this disclosure. Although illustrated as a single memory (3206) in FIG. 32, two or more memories may be used according to particular needs, desires, or particular implementations of the computer (3202) and the described functionality. While memory (3206) is illustrated as an integral component of the computer (3202), in alternative implementations, memory (3206) can be external to the computer (3202).

The application (3207) is an algorithmic software engine providing functionality according to particular needs, desires, or particular implementations of the computer (3202), particularly with respect to functionality described in this disclosure. For example, application (3207) can serve as one or more components, modules, applications, etc. Further, although illustrated as a single application (3207), the application (3207) may be implemented as multiple applications (3207) on the computer (3202). In addition, although illustrated as integral to the computer (3202), in alternative implementations, the application (3207) can be external to the computer (3202).

There may be any number of computers (3202) associated with, or external to, a computer system containing computer (3202), each computer (3202) communicating over network (3230). Further, the term “client,” “user,” and other appropriate terminology may be used interchangeably as appropriate without departing from the scope of this disclosure. Moreover, this disclosure contemplates that many users may use one computer (3202), or that one user may use multiple computers (3202).

In some embodiments, the computer (3202) is implemented as part of a cloud computing system. For example, a cloud computing system may include one or more remote servers along with various other cloud components, such as cloud storage units and edge servers. In particular, a cloud computing system may perform one or more computing operations without direct active management by a user device or local computer system. As such, a cloud computing system may have different functions distributed over multiple locations from a central server, which may be performed using one or more Internet connections. More specifically, cloud computing system may operate according to one or more service models, such as infrastructure as a service (IaaS), platform as a service (PaaS), software as a service (SaaS), mobile “backend” as a service (MBaaS), serverless computing, artificial intelligence (AI) as a service (AIaaS), and/or function as a service (FaaS).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed:

1. A method to perform reservoir simulation of a reservoir, comprising:
generating a simulation grid to represent the reservoir for the reservoir simulation, the simulation grid comprising a matrix grid and a continuum grid that superimpose each other, wherein each of a plurality of matrix cells of the matrix grid corresponds to one of a plurality of continuum cells of the continuum grid, wherein said each of the plurality of matrix cells stores corresponding rock properties of the reservoir;
obtaining fracture geometry data that represents a fracture polygon of each of a plurality of fractures in the reservoir;
obtaining well trajectory data that represents well segments of each of a plurality of wellbores in the reservoir;
dividing, based on the matrix grid, each fracture polygon into a set of fracture cells;
calculating fracture cell geometry data that represents each fracture cell of the plurality of fractures;
storing, for said each fracture cell, the fracture cell geometry data in a continuum cell of the plurality of continuum cells, wherein the continuum cell corresponds to a matrix cell of the plurality of matrix cells that contains said each fracture cell;
calculating matrix-fracture connections and fracture-fracture connections, wherein the matrix-fracture connections represent connectivity between the plurality of matrix cells and each fracture cell of the plurality of fractures, wherein the fracture-fracture connections represent connectivity among all fracture cells of the plurality of fractures;
calculating wellbore-fracture connections, wherein the wellbore-fracture connections, comprising perforation locations and productivity indices, represent the connectivity between plurality of fracture cells and well segments of a plurality of well trajectories;
generating a reservoir simulation result by performing the reservoir simulation based on the matrix grid with stored rock properties, the continuum grid with stored fracture cell geometry data, the matrix-fracture connections, the fracture-fracture connections, and the wellbore-fracture connections; and
performing, based on the reservoir simulation result, well production of the reservoir.

2. The method of claim 1, further comprising:
dividing the simulation grid into a plurality of partitions; and
allocating the plurality of partitions to a plurality of computer processors,
wherein calculating the fracture cell geometry data, the matrix-fracture connections, the fracture-fracture connections, and wellbore-fracture connections are performed by each of the plurality of computer processors for a corresponding partition of the simulation grid.

3. The method of claim 1, wherein calculating the matrix-fracture connections and the fracture-fracture connections comprises:
identifying two fracture cells divided from a single fracture polygon that are separately contained in two neighboring matrix cells of the matrix grid, wherein the fracture cell geometry data of the two fracture cells is separately stored in two neighboring continuum cells of the continuum grid that correspond to the two neighboring matrix cells;
establishing a matrix-fracture connection between each of the two neighboring continuum cells and a corresponding one of the two neighboring matrix cells; and
establishing an intra-fracture connection between the two neighboring continuum cells,
wherein the intra-fracture connection is an intra-continuum or inter-continuum neighboring connection between two neighboring matrix cells.

4. The method of claim 1, wherein calculating the matrix-fracture connections and the fracture-fracture connections comprises:
identifying, within a single matrix cell of the matrix grid, a total number of fracture cells from fracture polygons of the plurality of fractures;
extending the continuum grid to comprise an original matrix continuum grid and an extra fracture continuum grids that superimpose each other, wherein the single matrix cell corresponds to a matrix continuum cell of the original matrix continuum grid and a fracture continuum cell of each of the extra fracture continuum grids; and
establishing a matrix-fracture connection between the original matrix continuum cell and the fracture continuum cell of each of the extra fracture continuum grids,
wherein the fracture cell geometry data and equivalent fracture cell properties are stored separately in the added fracture continuum grid cells,
wherein the fracture cell geometry data comprises width, area, geometry shape, and distances to grid cell centers, and
wherein the equivalent fracture cell properties comprise transmissibility, porosity, and permeability.

5. The method of claim 4, wherein calculating the matrix-fracture connections and the fracture-fracture connections further comprises:
identifying that a first fracture cell and a second fracture cell intersect each other;
identifying, from a second fracture polygon and within a same matrix cell of the single matrix cell, a neighboring fracture cell of the second fracture cell; and
establishing an inter-fracture connection between a fracture cell in a first continuum grid and a fracture cell in a second continuum grid, both of which are in the same matrix cell,
wherein the inter-fracture connection is an inter-continua neighboring connection.

6. The method of claim 3,
wherein the two neighboring continuum cells are face-to-face neighbors in the continuum grid.

7. The method of claim 3,
wherein the two neighboring continuum cells are edge-to-edge neighbors in the continuum grid.

8. A modeling engine to facilitate reservoir simulation of a reservoir, comprising:
a computer processor; and
memory storing instructions, when executed by the computer processor comprising functionality for:
generating a simulation grid to represent the reservoir for the reservoir simulation, the simulation grid comprising a matrix grid and one or more continuum grids that superimpose each other, wherein each of a plurality of matrix cells of the matrix grid corresponds to one of a plurality of continuum cells of the continuum grids, wherein said each of the plurality of matrix cells stores corresponding rock properties of the reservoir;
obtaining fracture geometry data that represents a fracture polygon of each of a plurality of fractures in the reservoir;
dividing, based on the matrix grid, each fracture polygon into a set of fracture cells;
calculating fracture cell geometry data that represents each fracture cell of the plurality of fractures;
storing, for said each fracture cell, the fracture cell geometry data in a continuum cell of the plurality of continuum cells, wherein the continuum cell corresponds to a matrix cell of the plurality of matrix cells that contains said each fracture cell; and
calculating matrix-fracture connections, fracture-fracture connections, fracture-wellbore connections, wherein the matrix-fracture connections represent connectivity between the plurality of matrix cells and each fracture cell of the plurality of fractures, wherein the fracture-fracture connections represent connectivity among all fracture cells of the plurality of fractures, wherein the fracture-wellbore connections, comprising perforation locations and productivity indices, represent connectivity between fracture cells of the plurality of fractures and well segments of a plurality of well trajectories,
wherein a reservoir simulation result is generated by performing the reservoir simulation based on the matrix grid with stored rock properties, the continuum grid with stored fracture cell geometry data, the matrix-fracture connections, and the fracture-fracture connections, and the fracture-wellbore connections, and
wherein well production of the reservoir is performed based on the reservoir simulation result.

9. The modeling engine of claim 8, the instructions, when executed by the computer processor further comprising functionality for:
dividing the simulation grid into a plurality of partitions; and
allocating the plurality of partitions to a plurality of central processing units (CPUs) of the computer processor,
wherein calculating the fracture cell geometry data, the matrix-fracture connections, the fracture-fracture connections, and the fracture-wellbore connections are performed by each of the plurality of CPUs for a corresponding partition of the simulation grid.

10. The modeling engine of claim 8, wherein calculating the matrix-fracture connections and the fracture-fracture connections comprises:
identifying two fracture cells divided from a single fracture polygon that are separately contained in two neighboring matrix cells of the matrix grid, wherein the fracture cell geometry data of the two fracture cells is separately stored in two neighboring continuum cells of the continuum grid that correspond to the two neighboring matrix cells;
establishing a matrix-fracture connection between each of the two neighboring continuum cells and a corresponding one of the two neighboring matrix cells; and
establishing an intra-fracture connection between the two neighboring continuum cells,
wherein the intra-fracture connection is an intra-continuum neighboring connection.

11. The modeling engine of claim 8, wherein calculating the matrix-fracture connections and the fracture-fracture connections comprises:
identifying, within a single matrix cell of the matrix grid, a first fracture cell and a second fracture cell from a first fracture polygon and a second fracture polygon, respectively, of the plurality of fractures;
extending the continuum grid to comprise a first continuum grid and a second continuum grid that superimpose each other, wherein the single matrix cell corresponds to a first continuum cell of the first continuum grid and a second continuum cell of the second continuum grid; and
establishing a matrix-fracture connection between the single matrix cell and each of the first continuum cell and the second continuum cell,
wherein the fracture cell geometry data of the first fracture cell and the second fracture cell is separately stored in the first continuum cell and the second continuum cell, respectively.

12. The modeling engine of claim 11, wherein calculating the matrix-fracture connections and the fracture-fracture connections further comprises:
identifying that the first fracture cell and the second fracture cell intersect each other;
identifying, from the second fracture polygon and within a neighboring matrix cell of the single matrix cell, a neighboring fracture cell of the second fracture cell; and
establishing an inter-fracture connection between the first continuum cell and a neighboring continuum cell, in the second continuum, of the second continuum cell,
wherein the inter-fracture connection is an inter-continua neighboring connection.

13. The modeling engine of claim 12,
wherein the neighboring continuum cell and the second continuum cell are face-to-face neighbors in the second continuum grid.

14. The modeling engine of claim 12,
wherein the neighboring continuum cell and the second continuum cell are edge-to-edge neighbors in the second continuum grid.

15. A system comprising:
a wellsite for performing well production of a reservoir;
a modeling engine to facilitate reservoir simulation of the reservoir, comprising:
a computer processor; and
memory storing instructions, when executed by the computer processor comprising functionality for:
generating a simulation grid to represent the reservoir for the reservoir simulation, the simulation grid comprising a matrix grid and a continuum grid that superimpose each other, wherein each of a plurality of matrix cells of the matrix grid corresponds to one of a plurality of continuum cells of the continuum grid, wherein said each of the plurality of matrix cells stores corresponding rock properties of the reservoir;
obtaining fracture geometry data that represents a fracture polygon of each of a plurality of fractures in the reservoir;
obtaining well trajectory data that represents well segments of each of a plurality of wellbores in the reservoir;
dividing, based on the matrix grid, each fracture polygon into a set of fracture cells;
calculating fracture cell geometry data that represents each fracture cell of the plurality of fractures;
storing, for said each fracture cell, the fracture cell geometry data in a continuum cell of the plurality of continuum cells, wherein the continuum cell corresponds to a matrix cell of the plurality of matrix cells that contains said each fracture cell;
calculating matrix-fracture connections and fracture-fracture connections, wherein the matrix-fracture connections represent connectivity between the plurality of matrix cells and each fracture cell of the plurality of fractures, wherein the fracture-fracture connections represent connectivity among all fracture cells of the plurality of fractures; and
calculating wellbore-fracture connections, wherein the wellbore-fracture connections, comprising perforation locations and productivity indices, represent the connectivity between plurality of fracture cells and well segments of a plurality of well trajectories; and
a reservoir simulator that generates a reservoir simulation result by performing the reservoir simulation based on the matrix grid with stored rock properties, the continuum grid with stored fracture cell geometry data, the matrix-fracture connections, the fracture-fracture connections, and the wellbore-fracture connections,
wherein the well production of the reservoir is performed based on the reservoir simulation result.

16. The system of claim 15, the instructions, when executed by the computer processor further comprising functionality for:
dividing the simulation grid into a plurality of partitions; and
allocating the plurality of partitions to a plurality of central processing units (CPUs) of the computer processor,
wherein calculating the fracture cell geometry data, the matrix-fracture connections, the fracture-fracture connections, and wellbore-fracture connections are performed by each of the plurality of CPUs for a corresponding partition of the simulation grid.

17. The system of claim 15, wherein calculating the matrix-fracture connections and the fracture-fracture connections comprises:
identifying two fracture cells divided from a single fracture polygon that are separately contained in two neighboring matrix cells of the matrix grid, wherein the fracture cell geometry data of the two fracture cells is separately stored in two neighboring continuum cells of the continuum grid that correspond to the two neighboring matrix cells;
establishing a matrix-fracture connection between each of the two neighboring continuum cells and a corresponding one of the two neighboring matrix cells; and
establishing an intra-fracture connection between the two neighboring continuum cells,
wherein the intra-fracture connection is an intra-continuum or inter-continuum neighboring connection between two neighboring matrix cells.

18. The system of claim 15, wherein calculating the matrix-fracture connections and the fracture-fracture connections comprises:
identifying,
within a single matrix cell of the matrix grid, a total number of fracture cells from fracture polygons, of the plurality of fractures;
extending the continuum grid to comprise an original matrix continuum grid and extra fracture continuum grids that superimpose each other, wherein the single matrix cell corresponds to a matrix continuum cell of the original matrix continuum grid and a fracture continuum cell of each of the extra fracture continuum grids; and
establishing a matrix-fracture connection between the original matrix continuum cell and the fracture continuum cell of each of the extra fracture continuum grids,
wherein the fracture cell geometry data and equivalent fracture cell properties are stored separately in the added fracture continuum grid cells,
wherein the fracture cell geometry data comprises width, area, geometry shape, and distances to grid cell centers, and
wherein the equivalent fracture cell properties comprise transmissibility, porosity, and permeability.

19. The system of claim 18, wherein calculating the matrix-fracture connections and the fracture-fracture connections further comprises:
identifying that a first fracture cell and a second fracture cell intersect each other;
identifying, from a second fracture polygon and within a same matrix cell of the single matrix cell, a neighboring fracture cell of the second fracture cell; and
establishing an inter-fracture connection between a fracture cell in a first continuum grid and a fracture cell in a second continuum grid, both of which are in the same matrix cell,
wherein the inter-fracture connection is an inter-continua neighboring connection.

20. The system of claim 17,
wherein the two neighboring continuum cells are face-to-face neighbors or edge-to-edge neighbors in the second continuum grid.
